(19) United States
(12) Patent Application Publication
(10) Pub. No.: US 2026/0218697 A1
(43) Pub. Date: Jul. 30, 2026

(54) HAPTIC FEEDBACK DEVICE FOR VIRTUAL REALITY (VR) AND AUGMENTED REALITY (AR)

(71) Applicant: Taiwan Semiconductor Manufacturing Company, Ltd., Hsinchu (TW)

(72) Inventors: Chao-Hung Chu, Keelung City (TW); Ching-Hui Lin, Taichung City (TW); Shih-Fen Huang, Jhubei (TW)

(21) Appl. No.: 19/037,433

(22) Filed: Jan. 27, 2025

(51) Int. Cl. F04B 43/04; G06F 3/01; H10N 39/00

(52) U.S. Cl. CPC F04B 43/046; G06F 3/016; H10N 39/00

(57) ABSTRACT

Some embodiments relate to an integrated device, including: a first reservoir of low compressibility fluid contained by a first elastic compartment; a second reservoir of low compressibility fluid surrounded by a second elastic compartment; a first micropump structure including: a first cavity; a first piezoelectric pump lining a first side of the first cavity; a first electrostatic valve coupling the first reservoir to the first cavity; and a second electrostatic valve coupling the second reservoir to the first cavity; and a high voltage power source coupled to the first piezoelectric pump, the first electrostatic valve, and the second electrostatic valve; and control circuitry coupled to the high voltage power source.

### BACKGROUND

Virtual reality (VR) and augmented reality (AR) technology are used to immerse users in digital worlds and interact with digital reconstructions of objects for recreational and commercial purposes. Visual and auditory stimuli from devices coupled to the VR or AR technology are used to replace or overlap with stimuli from the real world, resulting in the users being able to respond to the sights and sounds as they would with physical objects. One challenge that these technologies face is how to implement haptic feedback for interacting with virtual elements.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIGS. 1A, 1B, and 1C illustrate an oblique view and cross-sectional views of some embodiments of a haptic feedback device utilizing a plurality of micropump structures.

FIGS. 2A-2B illustrates cross-sectional views of a first micropump structure within the haptic feedback device.

FIG. 3 illustrates a cross-sectional view of the first micropump structure of FIG. 2 in greater detail.

FIG. 4 illustrates a view of some embodiments of the haptic feedback device's positioning on a user's hand.

FIGS. 5-40, 41A, 41B, 42A, 42B, 43A, 43B, 44A, and 44B illustrate a series of cross-sectional views of some embodiments of a method of forming the haptic feedback device utilizing a plurality of micropump structures.

FIG. 45 illustrates a flowchart of some embodiments of a method of forming a haptic feedback device utilizing a plurality of micropump structures.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Virtual reality (VR) and augmented technology (AR) is used to immerse users in digital worlds and interact with digital reconstructions of objects for recreational and commercial purposes. Stimuli (e.g., visual, auditory, and haptic stimuli) from devices coupled to the VR or AR technology are used to replace or overlap with stimuli from the real world. While visual stimuli is provided through screens and auditory stimuli is provided through speakers (both well developed areas of technology), haptic stimuli is a more recent field of development and has many challenges to overcome.

Some embodiments for haptic stimuli utilize placeholder items that the user may interact with, in some cases with visual stimuli replacing or modifying that of the placeholder item. While these embodiments easily reproduce the haptic feedback received from interacting with a physical object, different VR or AR scenarios often have multiple different objects to interact with, and replacing the physical object the user is interacting with is disruptive to the immersion of the VR or AR experience. Other embodiments for haptic stimuli utilize gloves that cover the hands of the user and use internal mechanisms to simulate the haptic feedback of interacting with virtual objects. These devices are often bulky and cumbersome to use, however. Therefore, a lightweight device that simulates haptic feedback from interaction with virtual objects (e.g., objects simulated by VR or AR technology) without disrupting the immersive experience brought by VR or AR technology or being cumbersome to use is desirable.

The present disclosure provides for a wearable haptic feedback device utilizing a plurality of micropumps to simulate haptic feedback through restricting the range of movement of a user's finger joints. A plurality of micropumps are positioned between a first elastic compartment of low compressibility fluid and a second elastic compartment of low compressibility fluid. The first elastic compartment faces away from the finger joint and the second elastic compartment faces towards the finger joint. The haptic feedback device is held in place by a belt wrapped around the finger joint. When haptic feedback is desired (e.g., a simulated hand contacts a simulated object), a control circuitry causes the plurality of micropumps to pump low compressibility fluid from the first elastic compartment to the second elastic compartment. The higher volume of the second elastic compartment limits the range of joint movement of the finger joint, simulating contact with a physical object. When the simulated object is released (e.g., the simulated hand loses contact with the simulated object), the control circuitry causes the plurality of micropumps to pump low compressibility fluid from the second elastic compartment to the first elastic compartment. The lower volume of the second elastic compartment results in the finger joint having a greater range of joint movement, simulating the release of a physical object. As the haptic feedback device is mounted at the finger joints of the hand and uses components able to be fabricated using semiconductor fabrication techniques, the wearable haptic feedback device is lightweight, not overly cumbersome, and does not rely on the switching out of physical objects, resulting in a more immersive experience.

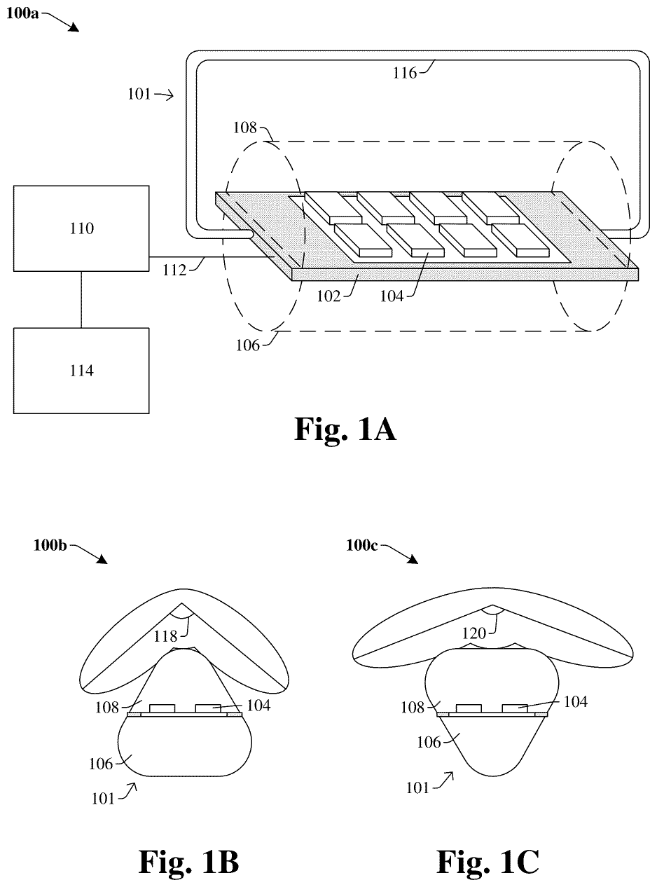

FIGS. 1A, 1B, and 1C illustrate an oblique view 100a and cross-sectional views 100b, 100c of some embodiments of a haptic feedback device utilizing a plurality of micropump structures.

A haptic feedback device 101 comprises a plurality of micropump structures 104 positioned on a device array fixture 102. The plurality of micropump structures 104 are connected through a first side of the device array fixture 102 to a first elastic compartment 106 filled with a low compressibility fluid. The plurality of micropump structures 104 are connected through a second side of the device array fixture 102 to the second elastic compartment 108 filled with the low compressibility fluid. In some embodiments, the first elastic compartment 106 and the second elastic compartment 108 are or comprise an elastic material (e.g., materials that may stretch to beyond their original dimensions and return without permanent deformation, such as rubber, polychloroprene, or the like) with a low permeability to fluids (e.g., an impermeable or substantially impermeable material). The first elastic compartment 106 and the second elastic compartment 108 are filled with a low compressibility fluid (e.g., fluids with a compressibility of less than approximately 10⁻⁹ m²/N, such as hydraulic oil or the like) with low conductivity (e.g., having a conductivity below approximately 10⁻⁹ siemens per meter).

The first elastic compartment 106 and the second elastic compartment 108 are both configured to expand and contract to contain a greater or lesser amount of low compressibility fluid than a baseline volume. In some embodiments, the baseline volume is the volume of the first elastic compartment 106 or the second elastic compartment 108 when the first elastic compartment 106 and the second elastic compartment 108 have an equal volume. In other embodiments, the first elastic compartment 106 and the second elastic compartment 108 are different sizes, and the baseline volume of the second elastic compartment 108 different from the baseline volume of the first elastic compartment 106. For example, in some embodiments, the first elastic compartment 106 and/or the second elastic compartment 108 expand and contract to have an internal volume that is 60% more or less than the baseline volume. In other embodiments, the first elastic compartment 106 and/or the second elastic compartment 108 expand and contract to have a change in internal volume 30%, 80%, 50%, or another similar difference from the baseline volume.

A belt 116 is attached to the device array fixture 102 at opposite ends of the device array fixture 102. The belt 116 surrounds the second elastic compartment 108 and the second side of the device array fixture 102. The belt is configured to affix device array fixture 102 to a finger joint with the second elastic compartment 108 facing towards the finger joint and the first elastic compartment 106 facing away from the finger joint.

A high voltage power source 110 (e.g., a power source transmitting voltages within a range of approximately 10 to 40 volts or the like) is coupled to the plurality of micropump structures 104 through a conductive wire 112. Control circuitry 114 is coupled to the high voltage power source 110 to control the electrical signals that are output from the high voltage power source 110. In some embodiments, the plurality of micropump structures 104 are on first integrated circuit chips, and the high voltage power source 110 and the control circuitry 114 are on one or more second integrated circuit chips separate from the first integrated circuit chips. The plurality of micropump structures 104 are configured to pump the low compressibility fluid from the first elastic compartment 106 to the second elastic compartment 108 or from the second elastic compartment to the first elastic compartment based on electrical signals received from the high voltage power source. In some embodiments, the control circuitry is configured to set the haptic feedback device to a “relaxed mode” or to a “grip mimicking mode” based on the interactions the user has with virtual objects. Examples of the “relaxed mode” and “grip mimicking mode” are described here after in relation to FIGS. 1B and 1C.

As shown in the cross-sectional view 100b of FIG. 1B, when the haptic feedback device 101 is directed to enter the “relaxed mode” (e.g., when the virtual representation of the user's hand lets go of or loses contact with a virtual object), the control circuitry (see 114 of FIG. 1A) uses the high voltage power source 110 to cause the plurality of micropump structures 104 to pump the low compressibility fluid from the second elastic compartment 108 to the first elastic compartment 106. Transferring the low compressibility fluid from the second elastic compartment 108 to the first elastic compartment 106 results in a reduction in the volume of the second elastic compartment 108. In some embodiments, the volume of the second elastic compartment 108 is reduced below the baseline volume of the second elastic compartment 108 by 30%, 50%, 70%, or another portion of the baseline volume. The reduction in volume of the second elastic compartment 108 results in the finger joint attached to the haptic control device having a first range of joint movement 118 (e.g., a first minimum angle that the finger joint can reach without being impeded by the second elastic compartment 108).

As shown in the cross-sectional view 100c of FIG. 1C, when the haptic feedback device 101 is directed to enter the “grip mimicking mode” (e.g., when the virtual representation of the user's hand comes into contact with or grabs onto a virtual object), the control circuitry (see 114 of FIG. 1A) uses the high voltage power source 110 to cause the plurality of micropump structures 104 to pump the low compressibility fluid from the first elastic compartment 106 to the second elastic compartment 108. Transferring the low compressibility fluid from the first elastic compartment 106 to the second elastic compartment 108 results in a increase in the volume of the second elastic compartment 108. In some embodiments, the volume of the second elastic compartment 108 is increased over the baseline volume of the second elastic compartment 108 by 30%, 50%, 70%, or another portion of the baseline volume. The increase in volume of the second elastic compartment 108 results in the finger joint attached to the haptic control device having a second range of joint movement 120 (e.g., a second minimum angle that the finger joint can contract to reach without being impeded by the second elastic compartment 108).

The second range of joint movement 120 is less than the first range of joint movement 118 as the second elastic compartment 108 impedes the motion of the finger joint in the “grip mimicking mode” to a greater degree than when the haptic feedback device is in the “relaxed mode.” In this way, the haptic feedback device delivers haptic feedback to the user about virtual objects in their environment without relying on physical props or overly cumbersome gloves.

In some embodiments, multiple separate “grip mimicking modes” are used to introduce different levels of haptic feedback. For example, in some embodiments, the volume of the second elastic compartment 108 is increased by a first portion of the baseline volume to simulate a first haptic feedback level (and a first corresponding range of joint movement), and the volume of the second elastic compartment 108 is increased by a second portion of the baseline volume to simulate a second haptic feedback level (and a second corresponding range of joint movement). A plurality of additional haptic feedback levels deliverable through different volumes of fluid in the second elastic compartment 108 and different corresponding ranges of joint movement can be readily envisioned and applied using the haptic feedback device 101. Further, providing haptic feedback for complex objects can be achieved by using multiple different haptic feedback devices 101 at different finger joints, and applying different levels of haptic feedback based on the position and orientation of the virtual object relative to the simulated hand. In this way, more complex haptic feedback can be provided to users, increasing the versatility of the device.

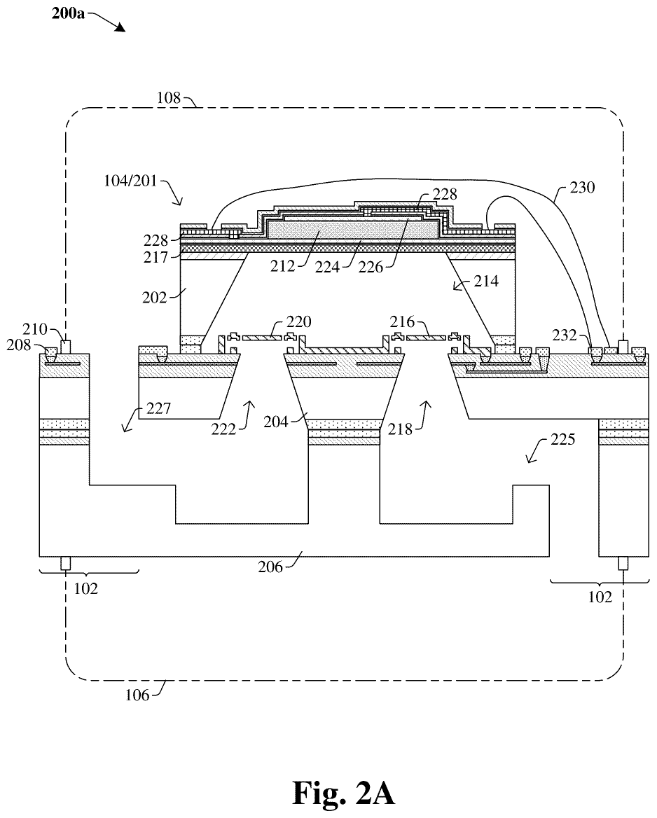

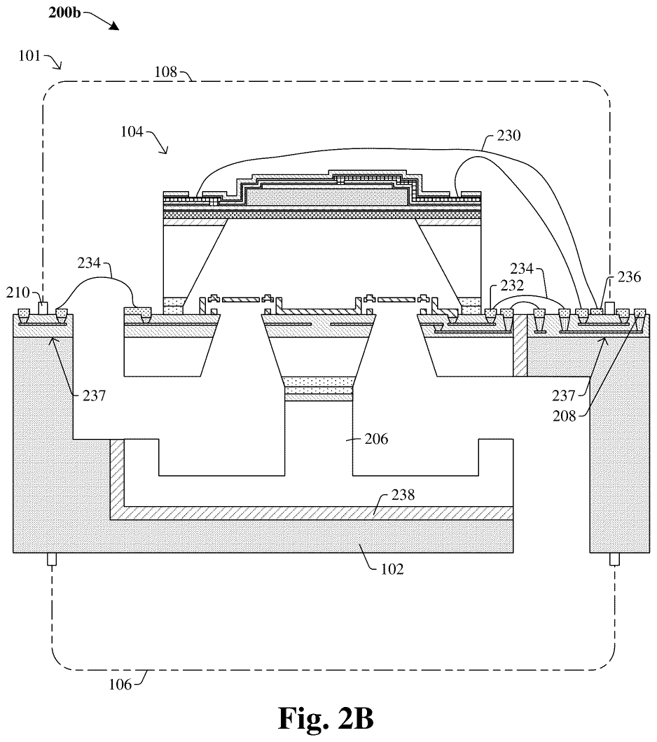

FIGS. 2A-2B illustrates cross-sectional views 200a, 200b of a first micropump structure within the haptic feedback device.

As shown in the cross-sectional view 200a of FIG. 2A, the plurality of micropump structures 104 comprise a plurality of substrates including a first substrate 202, a second substrate 204, and a third substrate 206. The plurality of micropump structures 104 comprises a first micropump structure 201. The first micropump structure 201 is within the second elastic compartment 108. It will be appreciated that in some embodiments the plurality of micropump structures 104 comprises an array of micropump structures (e.g., the first micropump structure 201 and a plurality of additional micropump structures), and that various embodiments with different numbers of micropump structures may be readily envisioned.

In some embodiments, the device array fixture 102 comprises peripheral regions of the second substrate 204 and the third substrate 206. In further embodiments, the device array fixture 102 comprises conductive contacts 208 to electrically couple the conductive wires (see 112 of FIG. 1A) to the plurality of micropump structures 104, as well as fixtures 210 for connecting the elastic material of the first and second elastic compartments to the device array fixture 102. The fixtures 210 are or comprise one or more of mechanical fixtures, bonding materials (e.g., glue or the like), or another type of connective material.

The first substrate 202 accommodates a piezoelectric ceramic 212. The piezoelectric ceramic 212 extends over a first cavity 214 in the first substrate 202. A flexible layer 217 extends between the piezoelectric ceramic 212 and the first cavity 214. In some embodiments, the piezoelectric ceramic 212 is configured to expand and contract based on electrical signals received from the high voltage power source. In other embodiments, the piezoelectric ceramic 212 is configured to bend away from the first cavity 214 and bend towards the first cavity 214 based on electrical signals received from the high voltage power source. The flexible layer 217 bends to accommodate the expansion and contraction of (or the bending away from and towards) the piezoelectric ceramic 212, respectively expanding or reducing the volume of the first cavity 214. The flexible layer 217 is also called the deflection membrane.

The second substrate 204 accommodates a first electrostatic valve 216 between the first cavity 214 and a first fluid opening 218 in the second substrate 204, as well as a second electrostatic valve 220 between the first cavity 214 and a first fluid opening 222 in the second substrate 204. The first electrostatic valve 216 and the second electrostatic valve 220 operate independently of the piezoelectric ceramic 212. During operation, the first electrostatic valve 216 and the second electrostatic valve are controlled to direct the flow of low compressibility fluid between the first and second elastic compartments 106, 108.

The third substrate 206 separates the first fluid opening 222 from the first elastic compartment 106. A first fluid pathway 225 extends through the third substrate 206 conducts low compressibility fluid from the first fluid opening 218 to the first elastic compartment 106. A second fluid pathway 227 extends through the third substrate 206 conducts low compressibility fluid from the second elastic compartment 108 to the second electrostatic valve 220. In some embodiments, the second fluid pathway 227 extends through the second substrate 204 and the third substrate 206.

To pump low compressibility fluid from the first elastic compartment 106 to the second elastic compartment 108, first, the first electrostatic valve 216 is opened, and the piezoelectric ceramic 212 is induced to expand (or bend away from the first cavity 214), resulting in the first cavity 214 containing a higher volume of the low compressibility fluid than when the piezoelectric ceramic 212 is in a neutral state. The added volume of low compressibility fluid is taken from the first elastic compartment 106. After the first cavity 214 reaches a high volume state, the first electrostatic valve 216 is closed and the second electrostatic valve 220 is opened. The piezoelectric ceramic 212 is subsequently induced to contract (or bend towards the first cavity 214), resulting in the first cavity 214 having a volume the same as or lower than when the piezoelectric ceramic 212 is in a neutral state. The reduction in volume induced by the contraction of the piezoelectric ceramic 212 pushes the low compressibility fluid through the second electrostatic valve 220 and into the second elastic compartment 108.

To pump low compressibility fluid from the first elastic compartment 106 to the second elastic compartment 108, the second electrostatic valve 220 is opened and the first electrostatic valve 216 is closed before the expansion (or convex bending) of the piezoelectric ceramic 212, resulting in the first cavity 214 reaching a high volume state and pulling the low compressibility fluid from the second elastic compartment 108. After the expansion of the piezoelectric ceramic 212, the first electrostatic valve 216 is opened and the second electrostatic valve 220 is closed before the contraction (or concave bending) of the piezoelectric ceramic 212 (and therefore the first cavity 214), resulting in the low compressibility fluid being transferred to the first elastic compartment 106. Repeating these steps results in low compressibility fluid being transferred from the first elastic compartment 106 to the second elastic compartment 108.

In some embodiments, the switching action of the piezoelectric ceramic 212, the first electrostatic valve 216, and the second electrostatic valve 220 may occur over twenty thousand times per second. Therefore, the micropump structures 104 may transfer low compressibility fluid between the first elastic compartment 106 to the second elastic compartment 108 over ten thousand times per second. The rapid pumping action of the first micropump structure 201 in addition to the simultaneous action of additional micropump structures 104 shown in some embodiments results in a lightweight haptic feedback device 101 with a rapid response time for VR and AR applications.

In some embodiments, the piezoelectric ceramic 212 is induced to expand and contract by applying electric signals to a lower electrode 224 and a upper electrode 226. In some embodiments, the electrical signals reach the lower electrode 224 and the upper electrode 226 through a combination of first conductive wires 228 on the first substrate 202 and second conductive wires 230 extending from the first substrate 202 to the conductive pads 232 on the second substrate 204. In other embodiments, the first conductive wires 228 are coupled to conductive pads 232 on the second substrate 204 using a through substrate via (TSV) or the like.

As shown in the cross-sectional view 200b of FIG. 2B, in some embodiments, the device array fixture 102 comprises a separate structure from the second substrate 204 and the third substrate 206. The device array fixture 102 having a separate structure to the plurality of substrates accommodating the plurality of micropump structures 104 results in stronger material options being available for the material composition of the device array fixture 102, resulting in a stronger chassis for the haptic feedback device 101.

In some embodiments, the device array fixture 102 comprises a semiconductor material, and semiconductor manufacturing processes (e.g., a plurality of etching, deposition, electroplating, and/or damascene processes) are used to form fixture contacts 236 and a second interconnect structure 237 onto the device array fixture 102. In other embodiments, the device array fixture 102 comprises a different material, and the semiconductor components (e.g., the fixture contacts 236 and the second interconnect structure 237) are affixed to the device array fixture 102 using mechanical or chemical (e.g., adhesive) means. Third conductive wires 234 couple conductive pads 232 of the plurality of micropump structures 104 to the fixture contacts 236 on the second interconnect structures 237. The fixture contacts 236 are coupled to conductive contacts 208 by means of either the second interconnect structure 237 or routing lines on the surface of the device array fixture to electrically couple the conductive wires (see 112 of FIG. 1A) to the plurality of micropump structures 104.

The plurality of micropump structures 104 are affixed to the device array fixture 102 by a bonding layer 238. In some embodiments, the bonding layer 238 comprises an adhesive. In other embodiments, the bonding layer 238 comprises another method of bonding the second and third substrate 204, 206 to the device array fixture 102 that is impermeable or substantially impermeable to the low compressibility fluid.

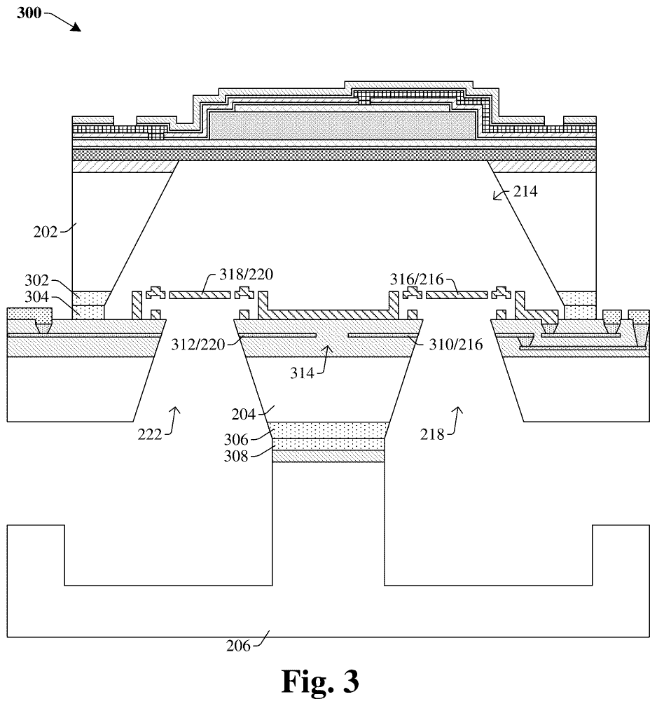

FIG. 3 illustrates a cross-sectional view 300 of the first micropump structure of FIG. 2 in greater detail.

In some embodiments, the first substrate 202, the second substrate 204, and the third substrate 206 are bonded together using a first bonding layer 302, a second bonding layer 304, a third bonding layer 306, and a fourth bonding layer 308. In further embodiments, the first, second, third, and fourth bonding layers 302, 304, 306, 308 independently are or comprise one or more of gold (Au), germanium (Ge), aluminum copper alloy (AlₓCu_{y}, where x and y are greater than 0), silicon (Si), silicon dioxide (SiO₂), tin (Sn), or the like. The materials of the coupled bonding layers (e.g., the first and second bonding layers 302, 304 and the third and fourth bonding layers 306, 308) are chosen in part based on their ability to form eutectic bonds between each other. For example, in some embodiments, the first bonding layer 302 comprises gold (Au) and the second bonding layer comprises aluminum copper alloy (AlₓCu_{y}, where x and y are greater than 0).

A first electrostatic induction wire 310 extends beneath the first electrostatic valve 216 within an interconnect structure 314 on the second substrate 204. A second electrostatic induction wire 312 extends beneath the second electrostatic valve 220 within the interconnect structure 314 on the second substrate 204. Operation of the first electrostatic valve 216 involves biasing the first electrostatic induction wire 310 and a first body structure 316 of the first electrostatic valve 216 with signals of opposite voltage. The attraction between the first body structure 316 and the first electrostatic induction wire 310 results in an upper portion of the first body structure 316 to bend downwards, isolating the first cavity 214 from the first fluid opening 218.

Operation of the second electrostatic valve 220 involves biasing the second electrostatic induction wire 312 and a second body structure 318 of the second electrostatic valve 220 with signals of opposite voltage. The attraction between the second body structure 318 and the second electrostatic induction wire 312 results in an upper portion of the second body structure 318 to bend downwards, isolating the first cavity 214 from the first fluid opening 222. In some embodiments, the first body structure 316 and the second body structure 318 are electrically coupled together, and actuation of the first and second electrostatic valves 216, 220 during operation is performed by changing the bias of the first and second electrostatic induction wire 310, 312, respectively.

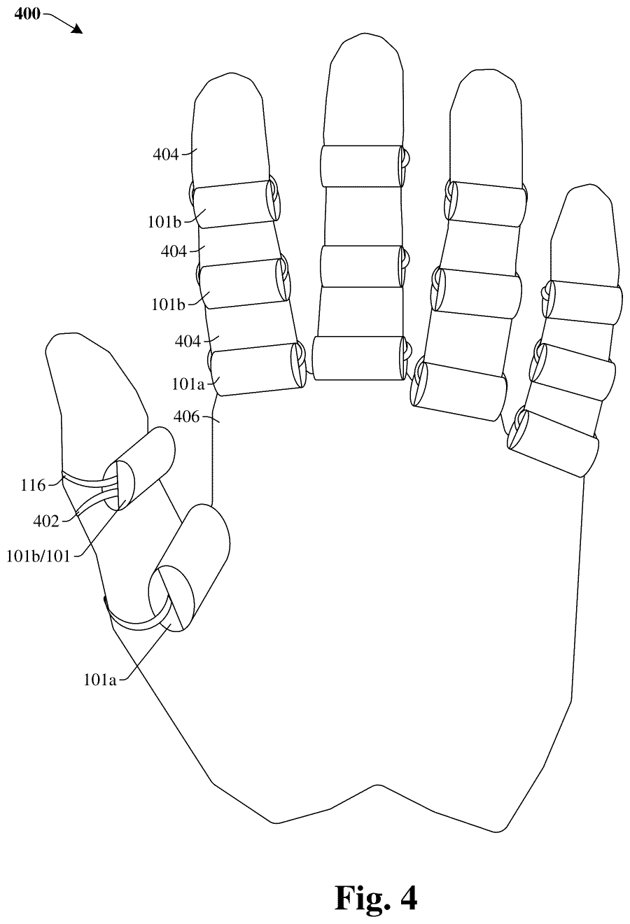

FIG. 4 illustrates a view 400 of some embodiments of the haptic feedback device's positioning on a user's hand.

In some embodiments, the haptic feedback device 101 and additional haptic feedback devices are positioned at each joint of the fingers and thumbs of a user's hand. The belt 116 of the haptic feedback device extends around the joint, holding the haptic feedback device in place and oriented with the second elastic compartment 108 facing the finger joint and the first elastic compartment 106 facing away from the finger joint. In some embodiments, one or more additional belts 402 or other methods are used to maintain the position of the haptic feedback device 101 on the user's hand. In some embodiments, different numbers of belts or other methods may be used by different haptic feedback devices on a user's hand. For example, in some embodiments, one belt is used to hold a first plurality of haptic feedback devices 101a at joints between phalanges 404 and a palm 406 in place, while multiple belts (comprising the additional belts 402) are used to hold a second plurality of haptic feedback devices 102b at joints between different phalanges 404 of the fingers in place.

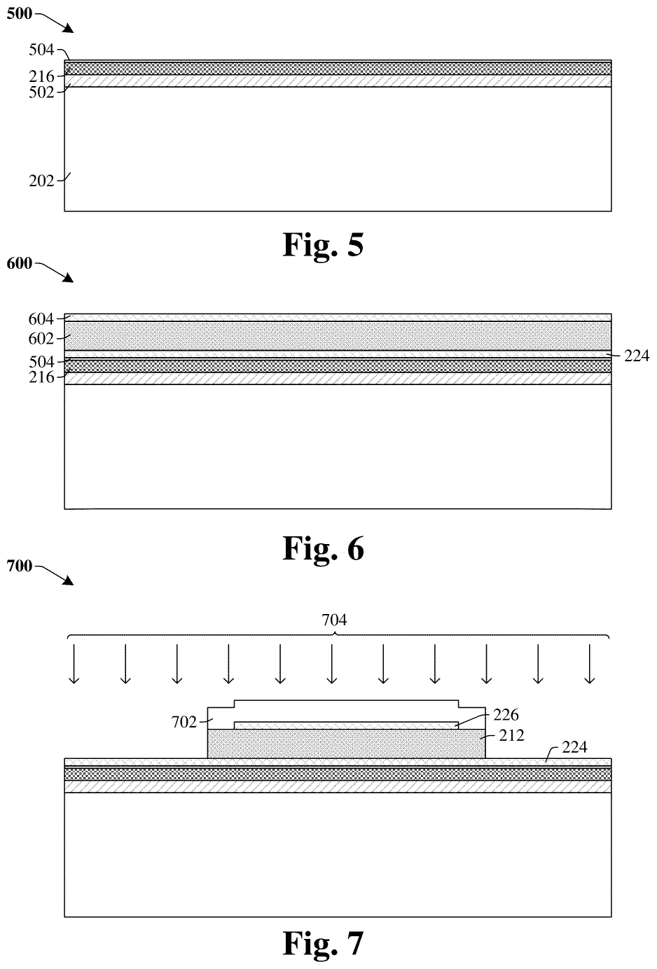

FIGS. 5-40, 41A, 41B, 42A, 42B, 43A, 43B, 44A, and 44B illustrate a series of cross-sectional views 500-4000, 4100a, 4100b, 4200a, 4200b, 4300a, 4300b, 4400a, 4400b of some embodiments of a method of forming the haptic feedback device utilizing a plurality of micropump structures. Although FIGS. 5-40, 41A, 41B, 42A, 42B, 43A, 43B, 44A, and 44B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 500 of FIG. 5, a first insulative layer 502, the flexible layer 217, and a first adhesion layer 504 are formed onto the first substrate 202. In some embodiments, the first insulative layer 502 is or comprises an insulative material, such as silicon dioxide (SiO₂), silicon nitride (Si₃N₄), aluminum oxide (Al₂O₃), boron nitride (BN), or the like. In some embodiments, the flexible layer 217 is or comprises a semiconductor material, such as silicon, germanium, or the like. In some embodiments, the first adhesion layer 504 is or comprises a metal oxide material, such as aluminum oxide (Al₂O₃), titanium oxide (TiO₂), zirconium oxide (ZrO₂), ruthenium oxide (RuO₂), zinc oxide (ZnO), chromium oxide (Cr₂O₃), or the like. In some embodiments, the first insulative layer 502, the flexible layer 217, and the first adhesion layer 504 are independently formed using one or more of a physical vapor deposition (PVD) process, an atomic layer deposition (ALD) process, a chemical vapor deposition (CVD) process, or the like.

In some embodiments, the first insulative layer 502 has a thickness approximately between 3 kilo-angstroms and 8 kilo-angstroms, approximately between 5 kilo-angstroms and 10 kilo-angstroms, approximately between 4 kilo-angstroms and 9 kilo-angstroms, or within another similar range. In some embodiments, the flexible layer 217 has a thickness approximately between 1 micrometer and 15 micrometers, approximately between 5 micrometers and 20 micrometers, approximately between 3 micrometers and 18 micrometers, or within another similar range. In some embodiments, the first adhesion layer 504 has a thickness approximately between 200 angstroms and 4 kilo-angstroms, approximately between 500 angstroms and 5 kilo-angstroms, approximately between 300 angstroms and 4.5 kilo-angstroms, or within another similar range.

As shown in the cross-sectional view 600 of FIG. 6, a lower electrode 224, a piezoelectric layer 602, and an upper electrode layer 604 are formed over the first adhesion layer 504. The first adhesion layer 504 provides a stronger bond to the lower electrode 224 than a direct bond to the flexible layer 217 would, reducing the amount of delamination and peeling between the lower electrode 224 and the flexible layer 217. The reduced degree of delamination and peeling results in a more effective micropump structure, as the coherence and bending of the flexible layer 217 in response to the expansion and contraction (or bending) of the piezoelectric results in the expansion and contraction of the volume of the first cavity (see 214 of FIG. 2).

In some embodiments, the lower electrode 224 and the upper electrode layer 604 are or comprise a conductive material, such as platinum (Pt), molybdenum (Mo), iridium (Ir), lithium nickel oxide (LiNiO₂), ruthenium oxide (RuO₂), or the like. In some embodiments, the piezoelectric layer 602 is or comprises a piezoelectric material, such as lead zirconate titanate (PZT), lithium tantalate (LiTaO₃), potassium sodium niobate (KNN), lanthanum-magnesium-lead titanate (LMN-PT) based piezo-ceramics, aluminum scandium nitride (Al₁₋ₓScₓN, where x is between 0 and 1), or the like. In some embodiments, the lower electrode 224 and the upper electrode layer 604 are independently formed using one of more of PVD, ALD, CVD, electroplating, or the like. In some embodiments, the piezoelectric layer 602 is formed using a sintering process followed by a poling process, or another method of forming piezoelectric materials.

In some embodiments, the lower electrode 224 and the upper electrode layer 604 have a thickness approximately between 1 kilo-angstroms and 8 kilo-angstroms, approximately between 3 kilo-angstroms and 10 kilo-angstroms, approximately between 2 kilo-angstroms and 9 kilo-angstroms, or within another similar range. In some embodiments, the piezoelectric layer 602 has a thickness approximately between 1 kilo-angstrom and 8 micrometers, approximately between 5 kilo-angstrom and 10 micrometers, approximately between 3 micrometers and 9 micrometers, or within another similar range.

As shown in the cross-sectional view 700 of FIG. 7, portions of the upper electrode layer (see 604 of FIG. 6) and the piezoelectric layer (see 602 of FIG. 6) are removed, resulting in the upper electrode 226 and the piezoelectric ceramic 212 remaining over the lower electrode 224. In some embodiments, the portions are removed using a first etching process (not shown) (e.g., an anisotropic dry etching process) to remove outer portions (e.g., portions outside of the layout of the first upper electrode 226) of the upper electrode layer (see 604 of FIG. 6) according to a first mask (not shown), and then subsequently etching the piezoelectric layer (see 602 of FIG. 6) and additional portions of the upper electrode layer (see 604 of FIG. 6) overlying the piezoelectric ceramic 212 with a second etching process 704 according to a second mask 702. In some embodiments, the first mask (not shown) and the second mask 702 are or comprise a photoresist patterned using photolithography. The first mask (not shown) and the second mask 702 are formed using a deposition process, a spin on process, a dipping process, or the like. After etching the upper electrode layer (see 604 of FIG. 6) into the upper electrode 226, the second mask 702 is removed.

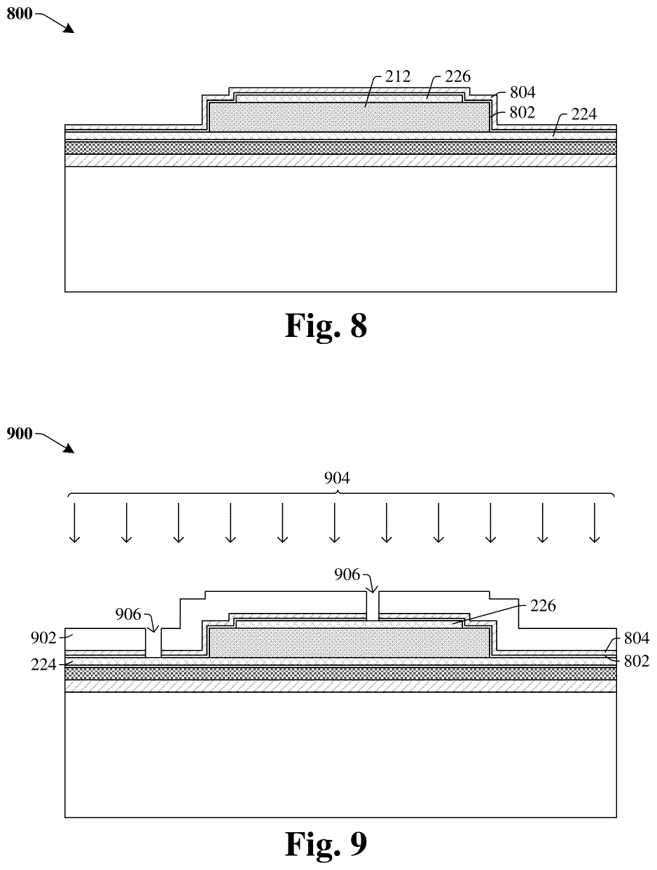

As shown in the cross-sectional view 800 of FIG. 8, a second adhesion layer 802 and a second insulative layer 804 is formed over the lower electrode 224, the piezoelectric ceramic 212, and the upper electrode 226. The second adhesion layer 802 and the second insulative layer 804 conform to outer sidewalls and upper surfaces of the lower electrode 224, the piezoelectric ceramic 212, and the upper electrode 226. In some embodiments, the second adhesion layer 802 is or comprises a same material as the first adhesion layer 504. In other embodiments, the second adhesion layer 802 is or comprises a different material, such as aluminum oxide (Al₂O₃), titanium oxide (TiO₂), zirconium oxide (ZrO₂), ruthenium oxide (RuO₂), zinc oxide (ZnO), chromium oxide (Cr₂O₃), or the like. In some embodiments, the second insulative layer 804 is or comprises a same material as the first insulative layer 502. In other embodiments, the second insulative layer 804 is or comprises a different material, such as silicon dioxide (SiO₂), silicon nitride (Si₃N₄), aluminum oxide (Al₂O₃), boron nitride (BN), or the like. In some embodiments, the second adhesion layer 802 and the second insulative layer 804 are independently formed using one of more of PVD, ALD, CVD, or the like.

As shown in the cross-sectional view 900 of FIG. 9, a third masking layer 902 is formed over the second insulative layer 804. In some embodiments, the third masking layer 902 is or comprises a photoresist and is patterned using photolithography. After forming the third masking layer 902, a third etching process 904 (e.g., a dry etching process or the like) is performed. The third etching process 904 results in first openings 906 being formed in the second adhesion layer 802 and the second insulative layer 804. The third masking layer 902 is subsequently removed.

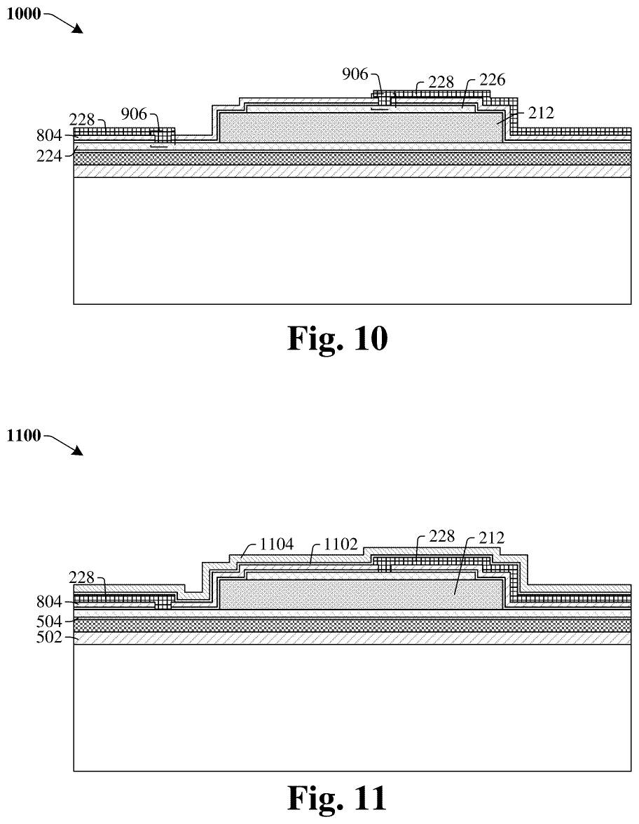

As shown in the cross-sectional view 1000 of FIG. 10, the first conductive wires 228 are formed over the second insulative layer 804 and within the first openings 906. The first conductive wires 228 comprise a first conductor adhesion layer and a first routing layer. In some embodiments, the first conductor adhesion layer is or comprises one or more of tantalum nitride (TaN), titanium nitride (TiN), titanium (Ti), tantalum (Ta), ruthenium (Ru), ruthenium oxide (RuO₂), or the like. In some embodiments, the first routing layer is or comprises one or more of copper (Cu), an aluminum copper alloy (AlₓCu_{y}, where x and y are greater than 0), aluminum (Al), tungsten (W), silver (Ag), gold (Au), cobalt (Co), a cobalt copper alloy (CuₓCo_{y}, where x and y are greater than 0), or the like. In some embodiments, the first conductor adhesion layer and the first routing layer are independently formed by one or more of a deposition process (e.g., CVD, ALD, PVD, or the like), an electroplating process, or the like. After the formation of the first conductor adhesion layer and the first routing layer, portions of the first conductor adhesion layer and the first routing layer are removed to form the first conductive wires 228. In some embodiments, the portions are removed using one or more masking and etching steps (not shown). The second insulative layer 804 protects the underlying layers (e.g., the piezoelectric ceramic 212, the upper and lower electrodes 226, 224) from damage during the one or more masking and etching steps.

As shown in the cross-sectional view 1100 of FIG. 11, a third adhesion layer 1102 and a third insulative layer 1104 is formed over the second insulative layer 804 and the first conductive wires 228. The third adhesion layer 1102 and the third insulative layer 1104 conform to outer sidewalls and upper surfaces of the second insulative layer 804 and the first conductive wires 228. In some embodiments, the third adhesion layer 1102 is or comprises a same material as the first adhesion layer 504. In other embodiments, the third adhesion layer 1102 is or comprises a different material, such as aluminum oxide (Al₂O₃), titanium oxide (TiO₂), zirconium oxide (ZrO₂), ruthenium oxide (RuO₂), zinc oxide (ZnO), chromium oxide (Cr₂O₃), or the like. In some embodiments, the third insulative layer 1104 is or comprises a same material as the first insulative layer 502. In other embodiments, the third insulative layer 1104 is or comprises a different material, such as silicon dioxide (SiO₂), silicon nitride (Si₃N₄), aluminum oxide (Al₂O₃), boron nitride (BN), or the like. In some embodiments, the third adhesion layer 1102 and the third insulative layer 1104 are independently formed using one of more of PVD, ALD, CVD, or the like. In some embodiments, the third insulative layer 1104 is a passivation layer configured to protect the underlying components (e.g., the piezoelectric ceramic 212) from damage.

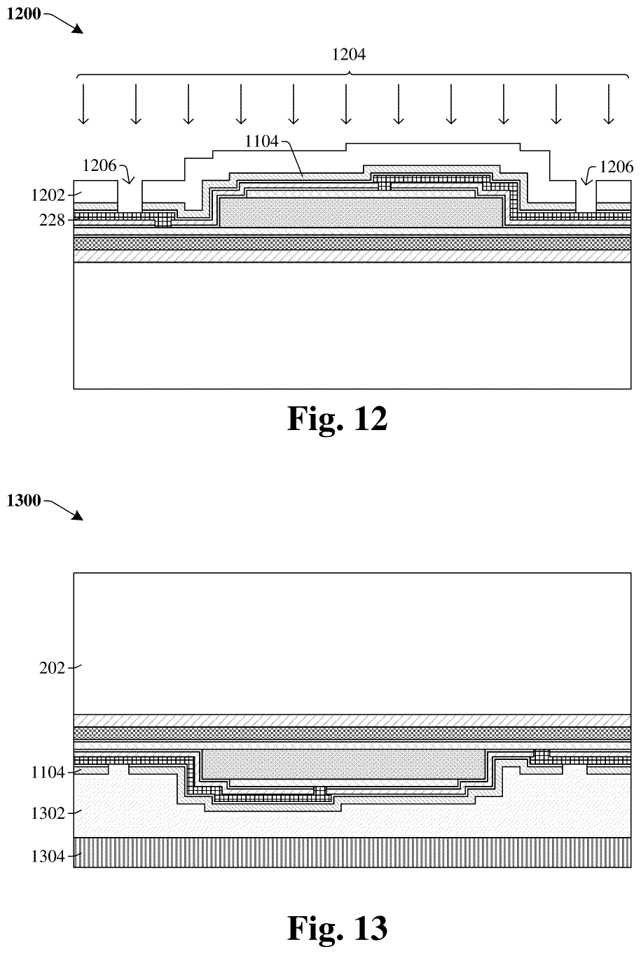

As shown in the cross-sectional view 1200 of FIG. 12, a fourth masking layer 1202 is formed over the third insulative layer 1104. In some embodiments, the fourth masking layer 1202 is formed using a deposition process, a spin on process, a dipping process, or the like. The fourth masking layer 1202 is then patterned. In some embodiments, the fourth masking layer 1202 is a photoresist and is patterned using photolithography. Openings in the fourth masking layer 1202 correspond to the position of second openings 1206 to be formed hereafter.

After the fourth masking layer 1202 is patterned, a fourth etching process 1204 is performed. In some embodiments, the fourth etching process 1204 is an anisotropic dry etching process. The fourth etching process 1204 results in the second openings 1206 being formed in the third insulative layer 1104 corresponding to where the second conductive wires (230 of FIG. 2) are coupled to the first conductive wires 228. The fourth masking layer 1202 is subsequently removed.

As shown in the cross-sectional view 1300 of FIG. 13, a first wafer adhesive layer 1302 is formed over the third insulative layer 1104 and a first carrier wafer 1304 is bonded to the first substrate 202 using the first wafer adhesive layer 1302. The first substrate 202 is then flipped over. In some embodiments, the first carrier wafer 1304 comprises a material such as glass or the like.

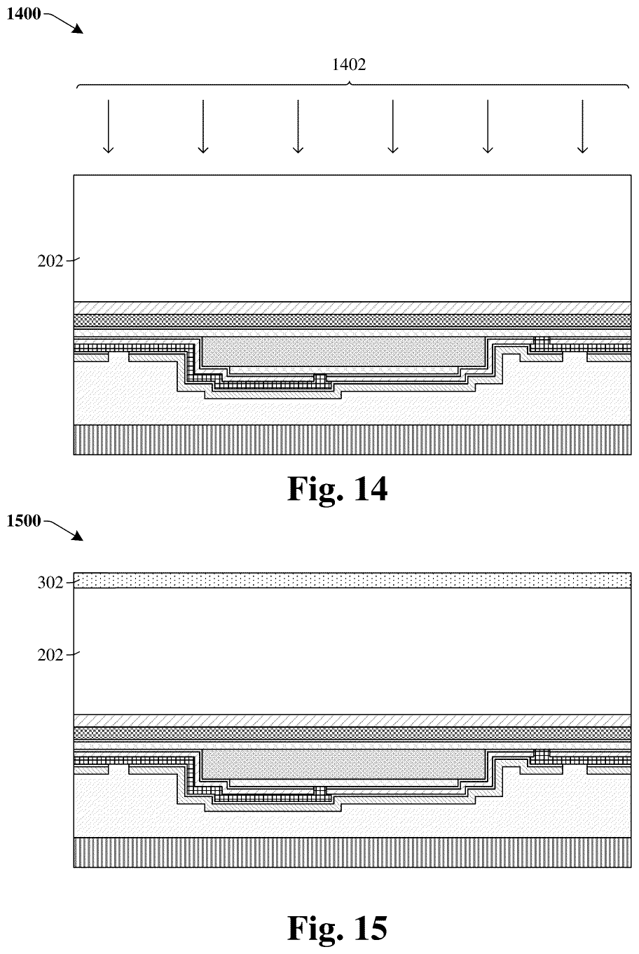

As shown in the cross-sectional view 1400 of FIG. 14, a grinding process 1402 is performed on the first substrate 202. In some embodiments, the grinding process 1402 is or comprises a planarization process (e.g., a chemical mechanical planarization (CMP) process). In some embodiments, the grinding process 1402 reduces the thickness of the first substrate to between approximately 300 to 450 micrometers, between approximately 350 to 500 micrometers, between approximately 325 to 475 micrometers, or within another similar range. The grinding process 1402 results in the first substrate 202 having a substantially flat surface.

As shown in the cross-sectional view 1500 of FIG. 15, the first bonding layer 302 is formed over the first substrate 202. In some embodiments, the first bonding layer 302 is or comprises one or more of gold (Au), germanium (Ge), aluminum copper alloy (AlₓCu_{y}, where x and y are greater than 0), silicon (Si), silicon dioxide (SiO₂), tin (Sn), or the like. In some embodiments, the first bonding layer 302 is formed using one or more of a deposition process (e.g., CVD, ALD, PVD, or the like) or the like.

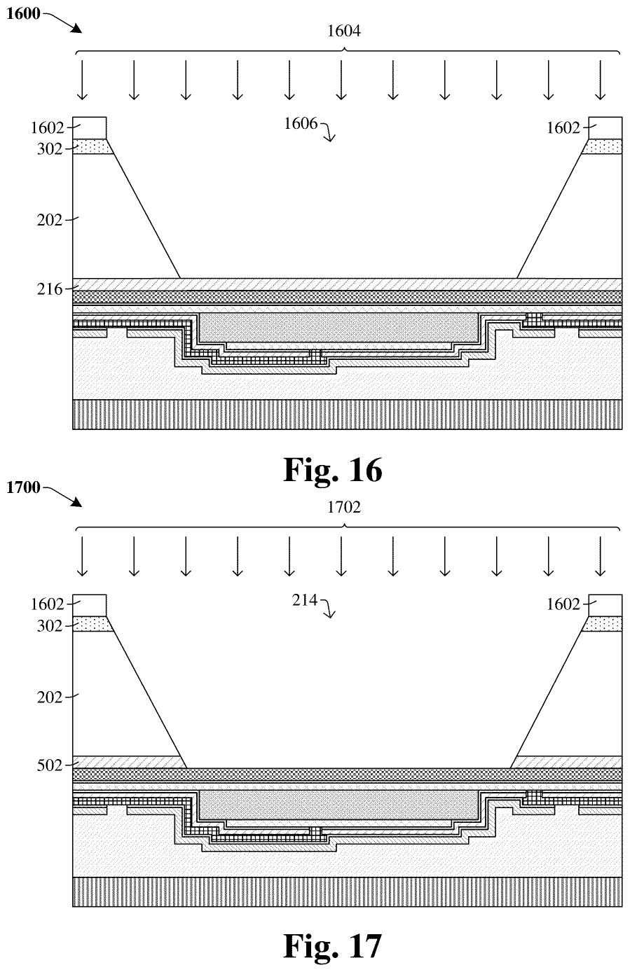

As shown in the cross-sectional view 1600 of FIG. 16, a fifth masking layer 1602 is formed over the first substrate 202. In some embodiments, the fifth masking layer 1602 is formed using a deposition process, a spin on process, a dipping process, or the like. The fifth masking layer 1602 is then patterned. In some embodiments, the fifth masking layer 1602 is a photoresist and is patterned using photolithography. The opening in the fifth masking layer 1602 correspond to the position of a third opening 1606 to be formed hereafter.

After the fifth masking layer 1602 is patterned, a fifth etching process 1604 is performed. In some embodiments, the fifth etching process 1604 is an anisotropic dry etching process. The fifth etching process 1604 results in the third opening 1606 being formed in the first substrate 202 and the first bonding layer 302 corresponding to the first cavity (see 214 of FIG. 2A). In some embodiments, the fifth masking layer 1602 is subsequently removed. In other embodiments, the fifth masking layer 1602 is not removed until after the subsequent etching step (shown hereafter in FIG. 17).

As shown in the cross-sectional view 1700 of FIG. 17, a sixth etching process 1702 is performed. In some embodiments, the sixth etching process 1702 is an anisotropic dry etching process. The sixth etching process 1702 results in the third opening (see 1606 of FIG. 16) extending through the first insulative layer 502, resulting in the first cavity 214. In some embodiments, the fifth masking layer 1602 is subsequently removed. In other embodiments, the fifth masking layer 1602 is removed before the sixth etching process 1702, and a sixth masking layer (not shown) is formed over the first bonding layer 302 to replace the fifth masking layer 1602. The sixth bonding layer (not shown) is then removed after the sixth etching process.

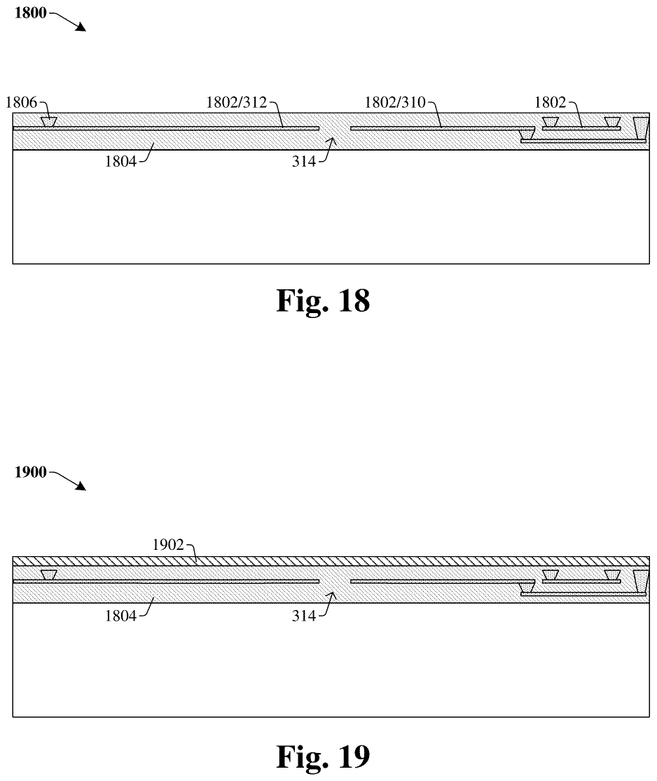

As shown in the cross-sectional view 1800 of FIG. 18, the interconnect structure 314 is formed on the second substrate 204. The interconnect structure 314 comprises a plurality of wire layers and a plurality of via layers configured to conduct electric signals to the first electrostatic induction wire 310, the second electrostatic induction wire 312, and the first and second body structures (see 316, 318 of FIG. 3) to be formed hereafter. A passivation layer 1804 surrounds the plurality of wire layers and the plurality of via layers.

In some embodiments, the plurality of wire layers are formed by depositing (e.g., using ALD, CVD, PVD or the like) a conformal conductive layer (not shown). The conformal conductive layer (not shown) is subsequently patterned into conductive wires 1802 using a combination of forming and patterning a mask (not shown) with overlying portions corresponding to the location of the conductive wires 1802, then patterning the conformal conductive layer (not shown) according to the mask (not shown). A passivation layer 1804 is subsequently formed (e.g., using ALD, CVD, PVD or the like) over the conductive wires 1802. A portion of the passivation layer overlying the conductive wires 1802 is then removed using a planarization process (e.g., a CMP process).

In some embodiments, the plurality of via layers are formed by depositing (e.g., using ALD, CVD, PVD or the like) a portion of the passivation layer 1804. The portion of the passivation layer 1804 is subsequently patterned to form via openings (not shown) using a combination of forming and patterning a mask (not shown) with openings corresponding to the location of the conductive vias 1806, then patterning the portion of the passivation layer 1804 according to the mask (not shown). A conformal conductive layer (not shown) is subsequently formed (e.g., using ALD, CVD, PVD or the like) over the remaining portion of the passivation layer 1804, filling the via openings. A portion of the conformal conductive layer (not shown) overlying the portion of the passivation layer 1804 is then removed using a planarization process (e.g., a CMP process), leaving the conductive vias 1806 within the via openings.

In some embodiments, the conductive wires 1802 are or comprise conductive material, such as doped silicon (silicon doped with n-type or p-type dopants), doped germanium (germanium doped with n-type or p-type dopants), a conductive metal, or the like. In some embodiments, the conductive wires 1802 have a thickness between approximately 1 and 20 kilo-angstroms, 3 and 30 kilo-angstroms, 2 and 25 kilo-angstroms, or the like. The conductive wires 1802 accommodate the first electrostatic induction wire 310 and the second electrostatic induction wire 312.

In some embodiments, the conductive vias 1806 independently comprise a second conductor adhesion layer and a metal via layer. In some embodiments, the second conductor adhesion layers of the conductive vias 1806 are or comprise one or more of tantalum nitride (TaN), titanium nitride (TiN), titanium (Ti), tantalum (Ta), ruthenium (Ru), ruthenium oxide (RuO₂), or the like. In some embodiments, the metal via layers of the conductive vias 1806 are or comprise one or more of copper (Cu), an aluminum copper alloy (AlₓCu_{y}, where x and y are greater than 0), aluminum (Al), tungsten (W), gold (Au), cobalt (Co), a cobalt copper alloy (CuₓCo_{y}, where x and y are greater than 0), or the like.

As shown in the cross-sectional view 1900 of FIG. 19, a first conformal doped semiconductor layer 1902 is formed on the passivation layer 1804 of the interconnect structure 314. In some embodiments, the first conformal doped semiconductor layer 1902 is or comprises a doped semiconductor material, such as doped silicon (silicon doped with n-type or p-type dopants), doped germanium (germanium doped with n-type or p-type dopants), or the like. In some embodiments, the first conformal doped semiconductor layer 1902 has a thickness between approximately 1 and 15 kilo-angstroms, 3 and 20 kilo-angstroms, 2 and 17 kilo-angstroms, or the like. In some embodiments, the first conformal doped semiconductor layer 1902 is formed using one or more of a deposition process (e.g., using ALD, CVD, PVD or the like), epitaxy (e.g., epitaxially growing the semiconductor layer with or without dopants), a subsequent doping process, or the like.

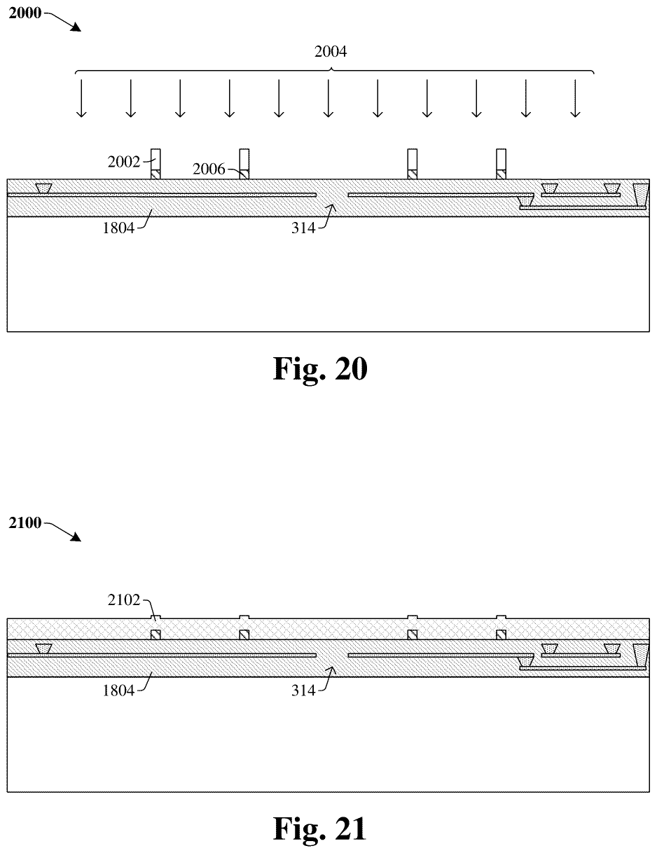

As shown in the cross-sectional view 2000 of FIG. 20, a seventh masking layer 2002 is formed over the first conformal doped semiconductor layer 1902. In some embodiments, the seventh masking layer 2002 is formed using a deposition process, a spin on process, a dipping process, or the like. The seventh masking layer 2002 is then patterned. In some embodiments, the seventh masking layer 2002 is a photoresist and is patterned using photolithography. Remaining portions of the seventh masking layer 2002 correspond to the position of buffer bumps 2006 to be formed hereafter.

After the seventh masking layer 2002 is patterned, a seventh etching process 2004 is performed. In some embodiments, the seventh etching process 2004 is an anisotropic dry etching process. The seventh etching process 2004 results in the buffer bumps 2006 remaining on the passivation layer 1804 of the interconnect structure 314. The seventh masking layer 2002 is subsequently removed. In some embodiments, the buffer bumps 2006 are configured to act as a buffer to prevent the flexible portions of the first and second electrostatic valves (see 216, 220 of FIG. 2) from hitting the harder material of the passivation layer 1804, preventing damage to both the passivation layer 1804 and the first and second electrostatic valves (see 216, 220 of FIG. 2).

As shown in the cross-sectional view 2100 of FIG. 21, a sacrificial insulator 2102 is deposited over the passivation layer 1804 of the interconnect structure 314. In some embodiments, the sacrificial insulator 2102 is or comprises an insulative material, such as silicon dioxide (SiO₂) or the like. In some embodiments, the sacrificial insulator 2102 has a thickness between approximately 3 and 30 kilo-angstroms, 5 and 50 kilo-angstroms, 4 and 40 kilo-angstroms, or another similar range. In some embodiments, the sacrificial insulator 2102 is formed using one or more of a deposition process (e.g., using ALD, CVD, PVD or the like), epitaxy (e.g., epitaxially growing a semiconductor layer) and a subsequent anneal, or the like.

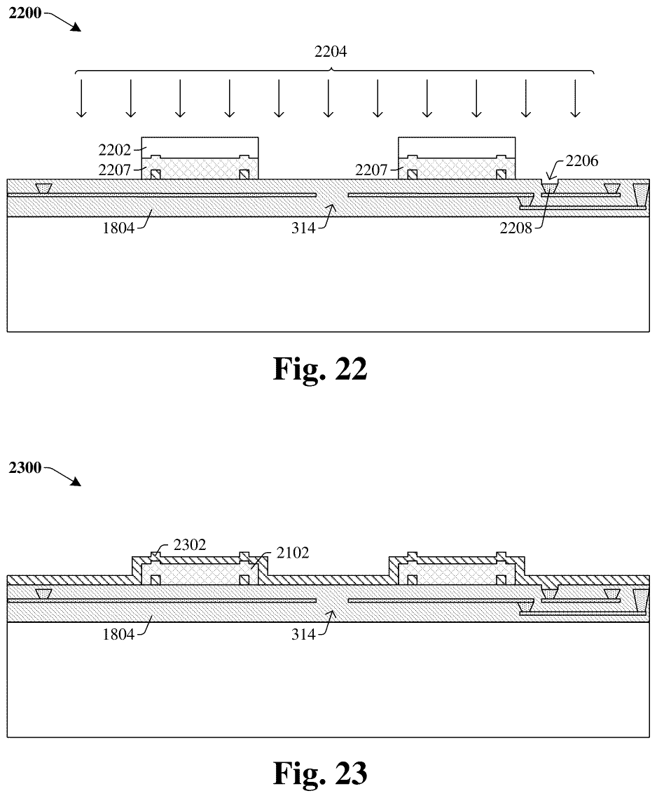

As shown in the cross-sectional view 2200 of FIG. 22, an eighth masking layer 2202 is formed over the sacrificial insulator (see 2102 of FIG. 21). In some embodiments, the eighth masking layer 2202 is formed using a deposition process, a spin on process, a dipping process, or the like. The eighth masking layer 2202 is then patterned. In some embodiments, the eighth masking layer 2202 is a photoresist and is patterned using photolithography. Remaining portions of the eighth masking layer 2202 correspond to the position of first and second electrostatic valves (see 216, 220 of FIG. 2) to be formed hereafter.

After the eighth masking layer 2202 is patterned, an eighth etching process 2204 is performed. In some embodiments, the eighth etching process 2204 is an anisotropic dry etching process. The eighth etching process 2204 results portions of the sacrificial insulator (see 2102 of FIG. 21) corresponding to the positions of the first and second electrostatic valves (see 216, 220 of FIG. 2) remaining on the passivation layer 1804 of the interconnect structure 314 as a mold structure 2207. The eighth masking layer 2202 is subsequently removed.

Further, after the eighth etching process 2204, a fourth opening 2206 is formed, exposing a first via 2208 of an uppermost via layer of the conductive vias 1806. The fourth opening 2206 is formed by forming and patterning a ninth masking layer (not shown) using a same method as forming and patterning the eighth masking layer 2202, then performing a ninth etch (not shown) to remove the portion of the passivation layer 1804 corresponding to the fourth opening 2206.

As shown in the cross-sectional view 2300 of FIG. 23, a second conformal doped semiconductor layer 2302 is deposited over the passivation layer 1804 of the interconnect structure 314. The second conformal doped semiconductor layer 2302 conforms to outer surfaces and upper sidewalls of the mold structure 2207. In some embodiments, the second conformal doped semiconductor layer 2302 is or comprises a doped semiconductor material, such as doped silicon (silicon doped with n-type or p-type dopants), doped germanium (germanium doped with n-type or p-type dopants), or the like. In some embodiments, the second conformal doped semiconductor layer 2302 has a thickness between approximately 1 and 30 kilo-angstroms, 5 and 50 kilo-angstroms, 3 and 40 kilo-angstroms, or another similar range. In some embodiments, the second conformal doped semiconductor layer 2302 is formed using one or more of a deposition process (e.g., using ALD, CVD, PVD or the like), epitaxy (e.g., epitaxially growing the semiconductor layer with or without dopants), a subsequent doping process, or the like.

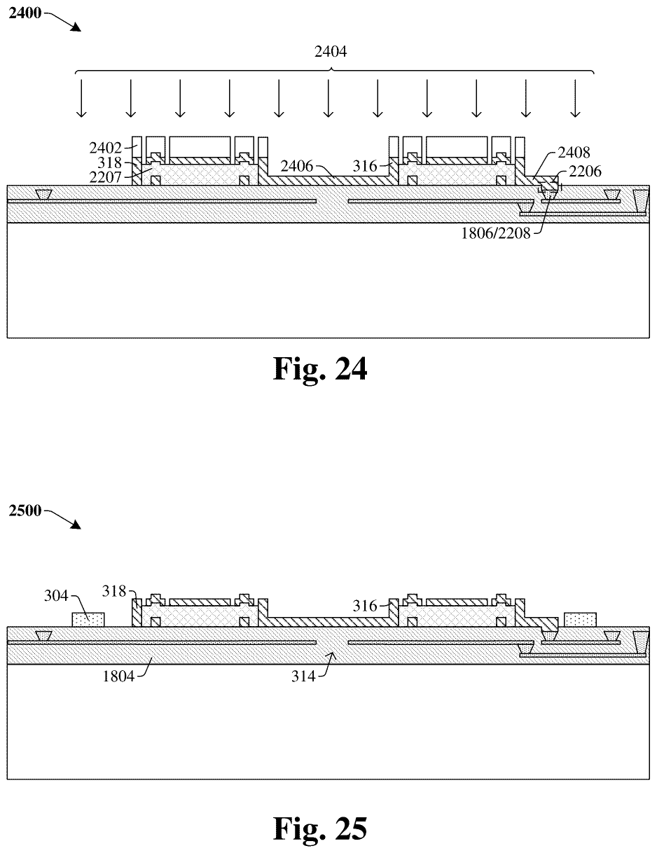

As shown in the cross-sectional view 2400 of FIG. 24, a tenth masking layer 2402 is formed over the second conformal doped semiconductor layer 2302. In some embodiments, the tenth masking layer 2402 is formed using a deposition process, a spin on process, a dipping process, or the like. The tenth masking layer 2402 is then patterned. In some embodiments, the tenth masking layer 2402 is a photoresist and is patterned using photolithography. Remaining portions of the tenth masking layer 2402 correspond to the position of the first and second body structures 316, 318 to be formed hereafter.

After the tenth masking layer 2402 is patterned, a tenth etching process 2404 is performed. In some embodiments, the tenth etching process 2404 is an anisotropic dry etching process. The tenth etching process 2404 results in portions of the second conformal doped semiconductor layer 2302 corresponding to the first and second body structures 316, 318 remaining on the passivation layer 1804 of the interconnect structure 314. A connective path 2406 extending between the first and second body structures 316, 318 further remains on the passivation layer, along with a second conductive path 2408 coupling the first and second body structures 316, 318 to the first via 2208 of the conductive vias 1806 through the fourth opening 2206 (shown in phantom). The tenth etching process 2404 further forms vent holes within the first and second body structures 316, 318, through which low compressibility fluid flows when the first and second electrostatic valves (see 216, 220 of FIG. 2) are open during operation. The tenth masking layer 2402 is subsequently removed.

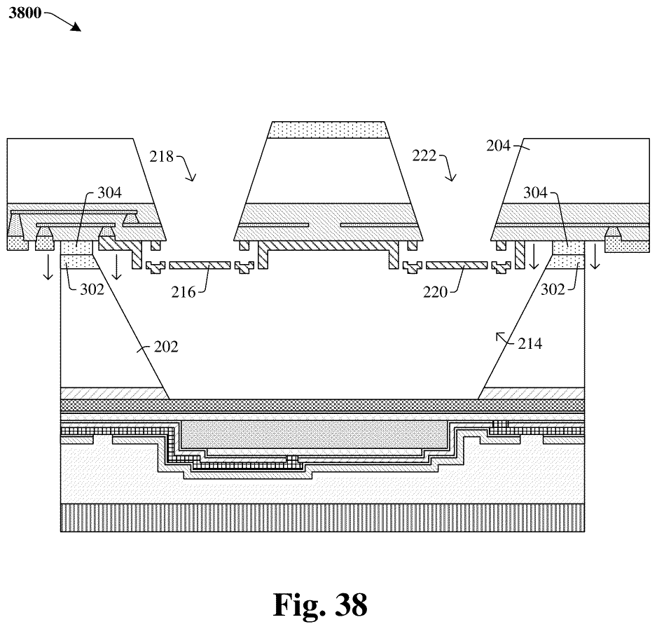

As shown in the cross-sectional view 2500 of FIG. 25, the second bonding layer 304 is formed on the passivation layer 1804 of the interconnect structure 314. In some embodiments, the second bonding layer 304 is or comprises one or more of gold (Au), germanium (Ge), aluminum copper alloy (AlₓCu_{y}, where x and y are greater than 0), silicon (Si), silicon dioxide (SiO₂), tin (Sn), or the like. In some embodiments, the second bonding layer 304 is formed by performing a deposition process (e.g., CVD, ALD, PVD, or the like) and a subsequent patterning process (e.g., a masking process followed by an etching process to remove material deposited that does not correspond to a final layout of the second bonding layer 304). The second bonding layer 304 comprises a plurality of segments entirely surrounding the first body structure 316 and the second body structure 318. The layout of the second bonding layer 304 is a mirrored version of the layout of the first bonding layer 302, to result in a unbroken seal around the first cavity (see 214 of FIG. 2) when the first bonding layer (see 302 of FIG. 3) is bonded to the second bonding layer 304 (see FIG. 38).

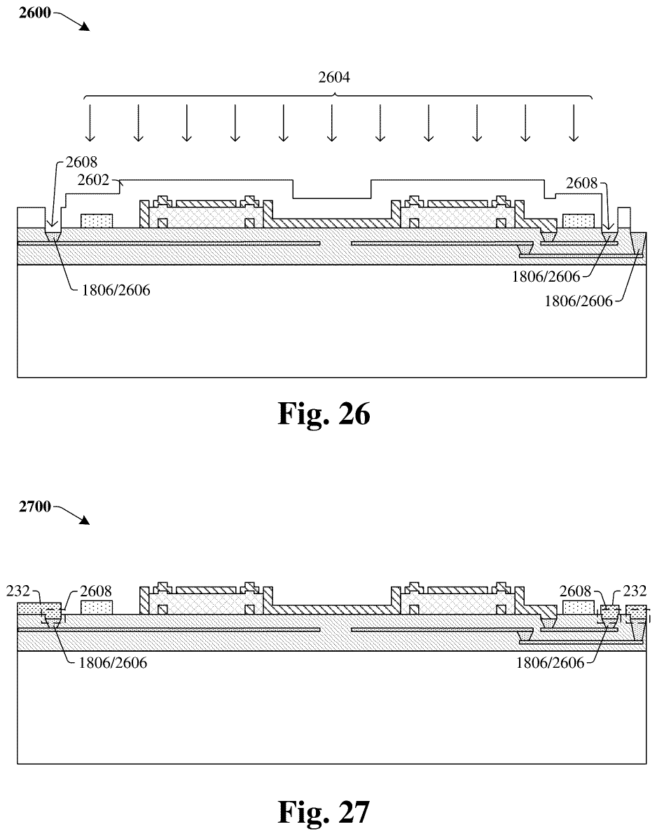

As shown in the cross-sectional view 2600 of FIG. 26, an eleventh masking layer 2602 is formed over the second bonding layer 304, the first body structure 316, and the second body structure 318. In some embodiments, the eleventh masking layer 2602 is formed using a deposition process, a spin on process, a dipping process, or the like. The eleventh masking layer 2602 is then patterned. In some embodiments, the eleventh masking layer 2602 is a photoresist and is patterned using photolithography. Remaining portions of the eleventh masking layer 2602 correspond to the position of second vias 2606 in an uppermost via layer of the conductive vias 1806 to be formed hereafter.

After the eleventh masking layer 2602 is patterned, an eleventh etching process 2604 is performed. In some embodiments, the eleventh etching process 2604 is an anisotropic dry etching process. The eleventh etching process 2604 results in the removal of portions of the passivation layer 1804 above the second vias 2606, exposing the second vias 2606 and forming fifth openings 2608. The eleventh masking layer 2602 is subsequently removed.

As shown in the cross-sectional view 2700 of FIG. 27, the conductive pads 232 are formed on the passivation layer 1804 of the interconnect structure 314. The conductive pads 232 fill the fifth openings 2608, electrically coupling to the second vias 2606. In some embodiments, a third conductor adhesion layer if formed before forming the conductive pads 232. In some embodiments, the third conductor adhesion layer of the conductive pads 232 comprises one or more of tantalum nitride (TaN), titanium nitride (TiN), titanium (Ti), tantalum (Ta), ruthenium (Ru), ruthenium oxide (RuO₂), or the like. In some embodiments, the conductive pads 232 comprise an inert metal, such as gold (Au), a gold alloy, tungsten (W), platinum (Pt), or the like.

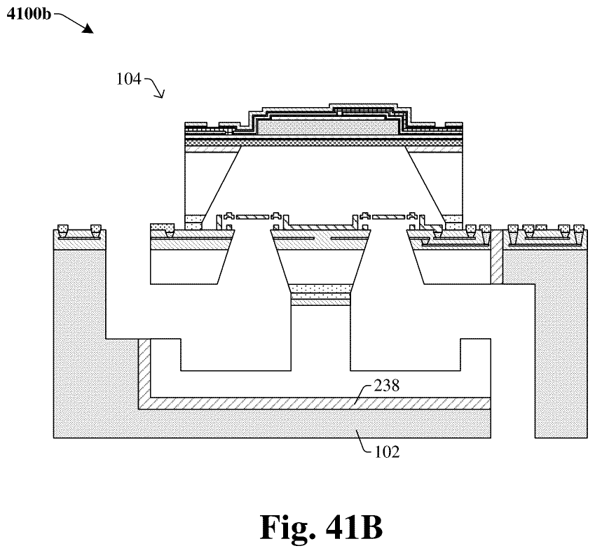

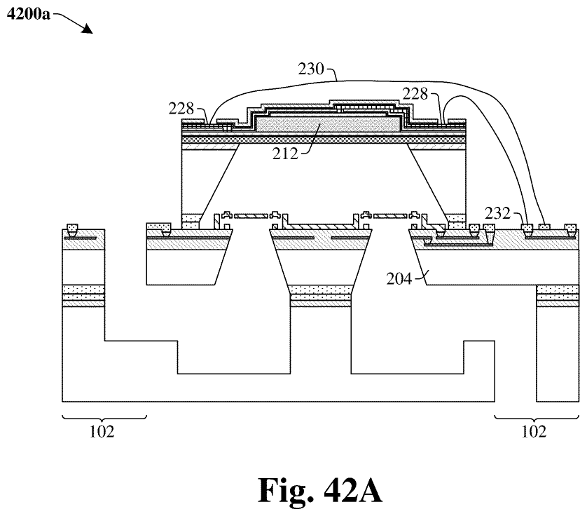

In some embodiments, the conductive pads 232 are formed by performing a deposition process (e.g., CVD, ALD, PVD, or the like) and a subsequent patterning process (e.g., a masking process followed by an etching process to remove material deposited that does not correspond to the conductive pads 232). The conductive pads 232 comprise a plurality of segments configured to electrically couple the interconnect structure 314, the second conductive wires 230 and/or the third conductive wires 234. The conductive pads 232 are configured to conduct electrical signals to the components of the first and second electrostatic valves 216, 220. In some embodiments, the conductive pads 232 are configured as an additional routing layer extending over the passivation layer 1804. In some embodiments, the conductive pads 232 are formed concurrently with the conductive contacts (see 208 of FIGS. 2A and 41A).

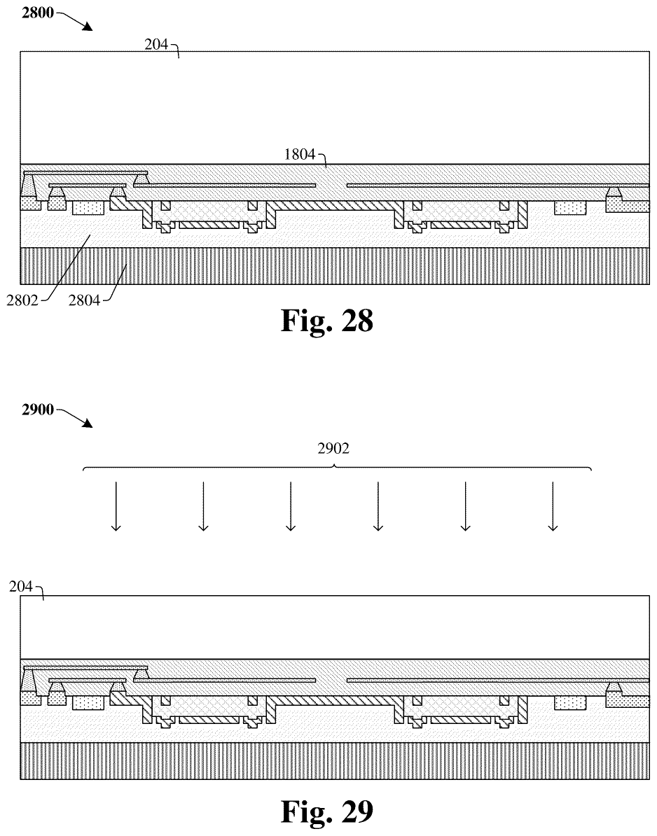

As shown in the cross-sectional view 2800 of FIG. 28, a second wafer adhesive layer 2802 is formed over the passivation layer 1804 and a second carrier wafer 2804 is bonded to the second substrate 204 using the second wafer adhesive layer 2802. The second substrate 204 is then flipped over, exposing a backside of the second substrate 204. In some embodiments, the second carrier wafer 2804 comprises a material such as glass or the like.

As shown in the cross-sectional view 2900 of FIG. 29, a second grinding process 2902 is performed on the second substrate 204. In some embodiments, the second grinding process 2902 is or comprises a planarization process (e.g., a chemical mechanical planarization (CMP) process). In some embodiments, the second grinding process 2902 reduces the thickness of the second substrate 204 to between approximately 200 to 400 micrometers, between approximately 300 to 500 micrometers, between approximately 250 to 450 micrometers, or within another similar range. The second grinding process 2902 results in the second substrate 204 having a substantially flat surface.

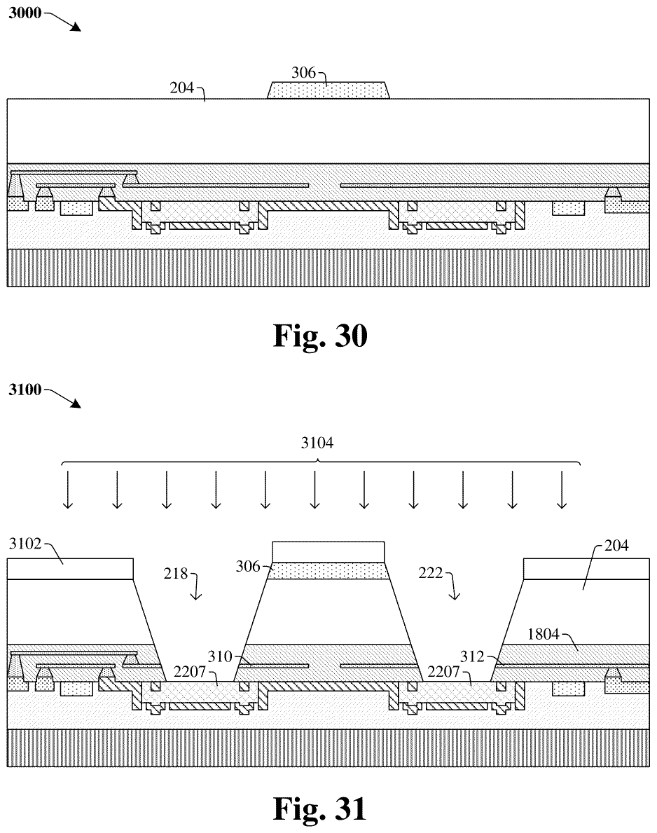

As shown in the cross-sectional view 3000 of FIG. 30, the third bonding layer 306 is formed on the second substrate 204. In some embodiments, the third bonding layer 306 is or comprises one or more of gold (Au), germanium (Ge), aluminum copper alloy (AlₓCu_{y}, where x and y are greater than 0), silicon (Si), silicon dioxide (SiO₂), tin (Sn), or the like. In some embodiments, the third bonding layer 306 is formed by performing a deposition process (e.g., CVD, ALD, PVD, or the like) and a subsequent patterning process (e.g., a masking process followed by an etching process to remove material deposited that does not correspond to the third bonding layer 306). The third bonding layer 306 extends between the first body structure 316 and the second body structure 318.

As shown in the cross-sectional view 3100 of FIG. 31, a twelfth masking layer 3102 is formed over the third bonding layer 306 and the second substrate 204. In some embodiments, the twelfth masking layer 3102 is formed using a deposition process, a spin on process, a dipping process, or the like. The twelfth masking layer 3102 is then patterned. In some embodiments, the twelfth masking layer 3102 is a photoresist and is patterned using photolithography. Openings in the twelfth masking layer 3102 correspond to the position of the first and second fluid openings 218, 222 to be formed hereafter.

After the twelfth masking layer 3102 is patterned, an twelfth etching process 3104 is performed. In some embodiments, the twelfth etching process 3104 is an anisotropic dry etching process. The twelfth etching process 3104 results in the removal of portions of the second substrate 204 and the passivation layer 1804, exposing the mold structure 2207 and the first and second electrostatic induction wires 310, 312. The first and second electrostatic induction wires 310, 312 surround the first fluid opening 218 and the first fluid opening 222 respectively. The twelfth masking layer 3102 is subsequently removed.

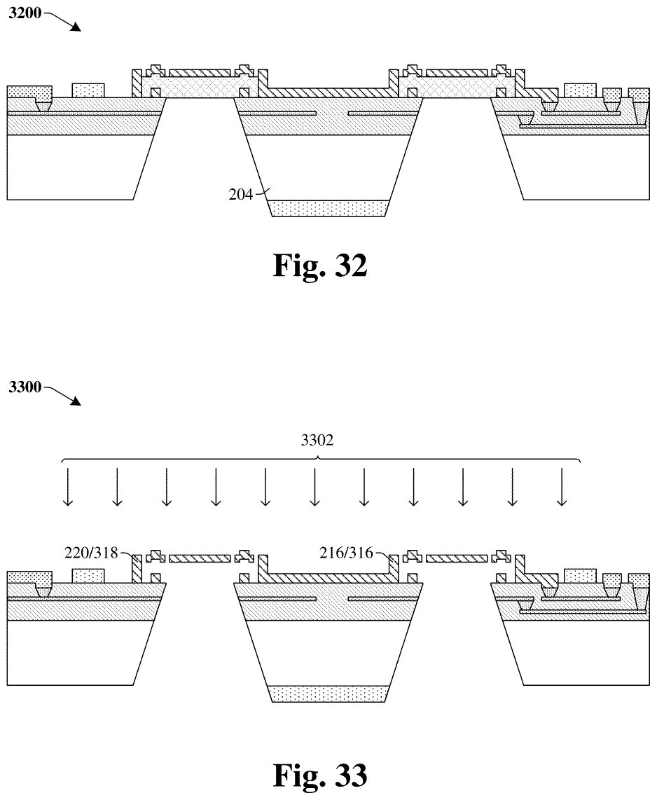

As shown in the cross-sectional view 3200 of FIG. 32, the second wafer adhesion layer (see 2802 of FIG. 28) and the second carrier wafer (see 2804 of FIG. 28) are removed from the passivation layer 1804. In some embodiments, the second wafer adhesion layer (see 2802 of FIG. 28) and the second carrier wafer (see 2804 of FIG. 28) are removed using a laser debonding process. In some embodiments, the second substrate 204 is then flipped over.

As shown in the cross-sectional view 3300 of FIG. 33, the mold structure (see 2207 of FIGS. 22 and 31) is removed. In some embodiments, the mold structure (see 2207 of FIGS. 22 and 31) is removed using a vapor etching process 3302 (e.g., a hydrogen fluoride (HF) vapor etching process or the like). The removal of the mold structure (see 2207 of FIGS. 22 and 31) creates openings through the first and second body structures 316, 318 and releases flexible stoppers of the first and second electrostatic valves 216, 220.

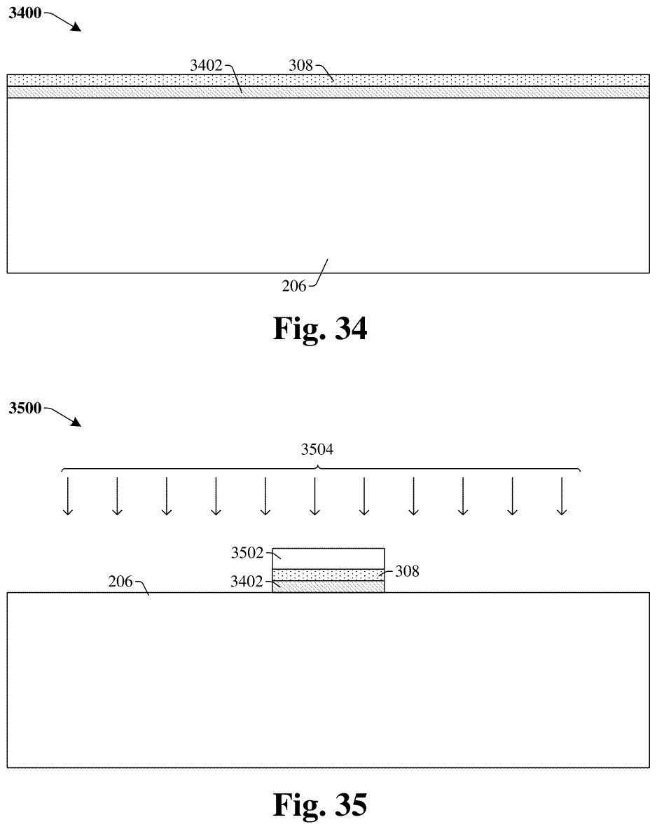

As shown in the cross-sectional view 3400 of FIG. 34, a third insulative layer 3402 and a fourth bonding layer 308 are deposited over the third substrate 206. In some embodiments, the third insulative layer 3402 is or comprises an insulative material, such as silicon nitride (Si₃N₄), aluminum nitride (AlN), hafnium oxide (HfO₂), zinc oxide (ZnO), silicon carbide (SiC), or the like. In some embodiments, the fourth bonding layer 308 is or comprises one or more of gold (Au), germanium (Ge), aluminum copper alloy (AlₓCu_{y}, where x and y are greater than 0), silicon (Si), silicon dioxide (SiO₂), tin (Sn), or the like. In some embodiments, the third insulative layer 3402 has a thickness between approximately 3 and 8 kilo-angstroms, 5 and 10 kilo-angstroms, 4 and 9 kilo-angstroms, or another similar range. In some embodiments, the fourth bonding layer 308 has a thickness between approximately 2 and 15 kilo-angstroms, 5 and 20 kilo-angstroms, 4 and 18 kilo-angstroms, or another similar range. In some embodiments, the third insulative layer 3402 and the fourth bonding layer 308 are independently formed using one or more deposition processes (e.g., using ALD, CVD, PVD or the like) or the like.

As shown in the cross-sectional view 3500 of FIG. 35, a thirteenth masking layer 3502 is formed over the fourth bonding layer 308. In some embodiments, the thirteenth masking layer 3502 is formed using a deposition process, a spin on process, a dipping process, or the like. The thirteenth masking layer 3502 is then patterned. In some embodiments, the thirteenth masking layer 3502 is a photoresist and is patterned using photolithography. Portions of the thirteenth masking layer 3502 correspond to a mirrored version of the third bonding layer (see 306 of FIGS. 3 and 30).

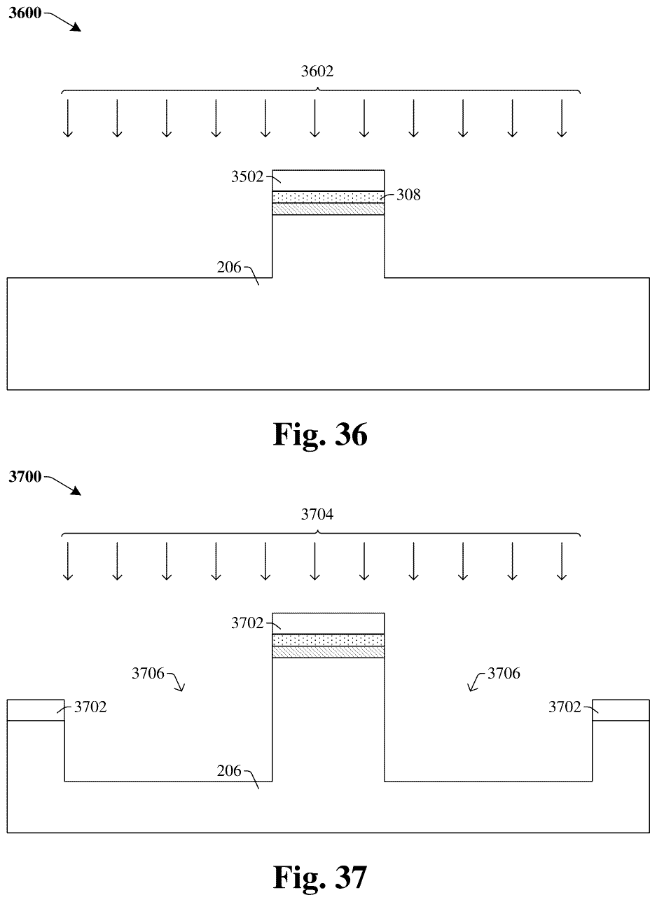

After the thirteenth masking layer 3502 is patterned, a thirteenth etching process 3504 is performed. In some embodiments, the thirteenth etching process 3504 is an anisotropic dry etching process. The thirteenth etching process 3504 results in the removal of portions of the fourth bonding layer 308 and the third insulative layer 3402, exposing the third substrate 206 and patterning the fourth bonding layer 308 to have a mirrored layout of the third bonding layer (see 306 of FIGS. 3 and 30). In some embodiments, the thirteenth masking layer 3502 is subsequently removed. In other embodiments, the thirteenth masking layer 3502 remains on substrate through the etching process to be performed hereafter (see FIG. 36).

As shown in the cross-sectional view 3600 of FIG. 36, a fourteenth etching process 3602 is performed. In some embodiments, the fourteenth etching process 3602 is an anisotropic dry etching process. The fourteenth etching process 3602 results in the removal of portions of the third substrate 206 to form a portion of the first fluid pathway (see 225 of FIG. 2A) and the second fluid pathway (see 227 of FIG. 2A). In some embodiments, the thirteenth masking layer 3502 is subsequently removed. In other embodiments, a fourteenth masking layer (not shown) is formed on the fourth bonding layer 308 after the thirteenth masking layer 3502 is removed, and the fourteenth masking layer (not shown) is removed after the fourteenth etching process 3602.

As shown in the cross-sectional view 3700 of FIG. 37, a fifteenth masking layer 3702 is formed over the fourth bonding layer 308 and low surfaces containing the first fluid pathway (see 225 of FIG. 2). In some embodiments, the fifteenth masking layer 3702 is formed using a deposition process, a spin on process, a dipping process, or the like. The fifteenth masking layer 3702 is then patterned. In some embodiments, the fifteenth masking layer 3702 is a photoresist and is patterned using photolithography. Portions of the fifteenth masking layer 3702 correspond to the positions of the fourth bonding layer 308 and lower surfaces lining the first and second fluid pathways (see 225, 227 of FIG. 2A).

After the fifteenth masking layer 3702 is patterned, a fifteenth etching process 3704 is performed. In some embodiments, the fifteenth etching process 3704 is an anisotropic dry etching process. The fifteenth etching process 3704 results in the removal of portions of the third substrate 206 corresponding to cavities 3706 underlying the first and second fluid openings (see 218, 222 of FIG. 2) and forming part of the first and second fluid pathways (see 225, 227 of FIG. 2A). The fifteenth masking layer 3702 is subsequently removed.

As shown in the cross-sectional view 3800 of FIG. 38, the second substrate 204 is bonded to the first substrate 202. The second substrate 204 is bonded to the first substrate 202 using a eutectic bonding process. The eutectic bonding process comprises using a combination of pressure and a low temperature anneal to cause the materials of the first bonding layer 302 and the second bonding layer 304 to form a eutectic system, with the resulting alloy becoming a liquid state below the melting points of the individual materials. The temperature of the low temperature anneal is chosen based on the material composition of the first bonding layer 302 and the second bonding layer 304. In some embodiments, the temperature of the low temperature anneal is approximately between 150 and 600 degrees Celsius, or within another similar range. The eutectic bonding process results in a seal between the first substrate 202 and the second substrate 204, such that the remaining openings in the first cavity 214 are through the first and second electrostatic valves 216, 220.

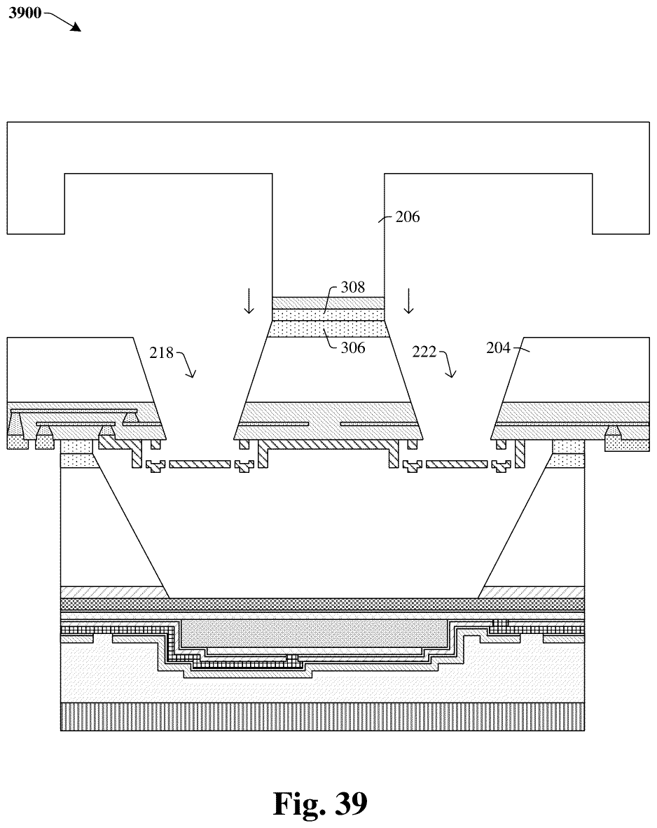

As shown in the cross-sectional view 3900 of FIG. 39, the third substrate 206 is bonded to the second substrate 204. The third substrate 206 is bonded to the second substrate 204 using a eutectic bonding process. The eutectic bonding process comprises using a combination of pressure and a low temperature anneal to cause the materials of the third bonding layer 306 and the fourth bonding layer 308 to form a eutectic system, with the resulting alloy becoming a liquid state below the melting points of the individual materials. The temperature of the low temperature anneal is chosen based on the material composition of the third bonding layer 306 and the fourth bonding layer 308. In some embodiments, the temperature of the low temperature anneal is approximately between 150 and 600 degrees Celsius, or within another similar range. The eutectic bonding process results in a seal between the third substrate 206 and the second substrate 204, such that the first and second fluid openings 218, 222 are separated by the third substrate 206.

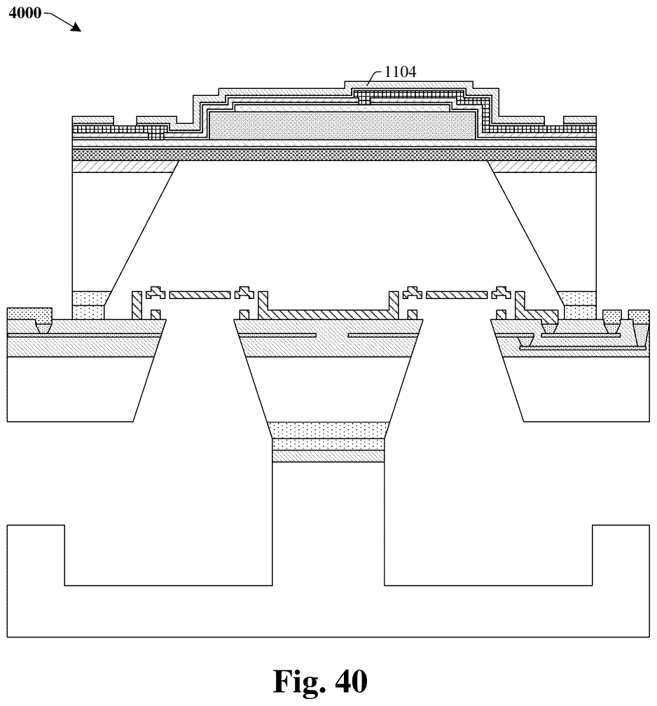

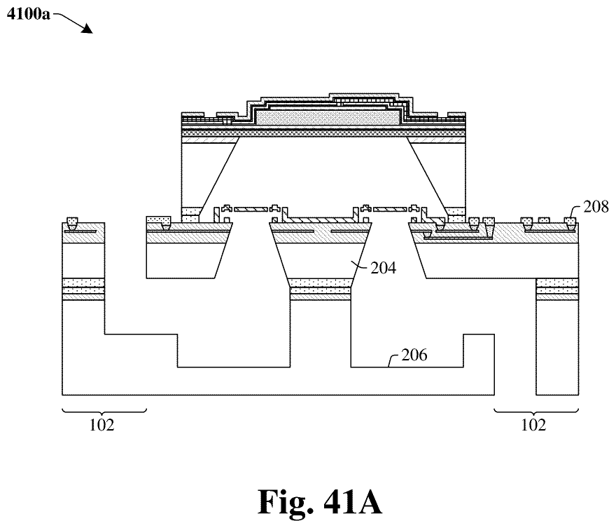

As shown in the cross-sectional view 4000 of FIG. 40, the first wafer adhesion layer (see 1302 of FIG. 13) and the first carrier wafer (see 1304 of FIG. 13) are removed from the third insulative layer 1104. In some embodiments, the first wafer adhesion layer (see 1302 of FIG. 13) and the first carrier wafer (see 1304 of FIG. 13) are removed using a laser debonding process. In some embodiments, the plurality of substrates (e.g., the first substrate 202, the second substrate 204, and the third substrate 206) are then flipped over.

As shown in the cross-sectional view 4100a of FIG. 41A, in some embodiments, the device array fixture 102 comprises portions of the second substrate 204 and the third substrate 206, and the device array fixture 102 is formed concurrently with steps corresponding to FIGS. 18-37. As shown in the cross-sectional view 4100b of FIG. 41B, in other embodiments, the device array fixture 102 is formed separately from the plurality of micropump structures 104. The device array fixture 102 is subsequently bonded to the plurality of micropump structures 104. In some embodiments, the device array fixture 102 is bonded to the plurality of micropump structures 104 using a bonding layer 238, a eutectic bonding process, or another bonding process.

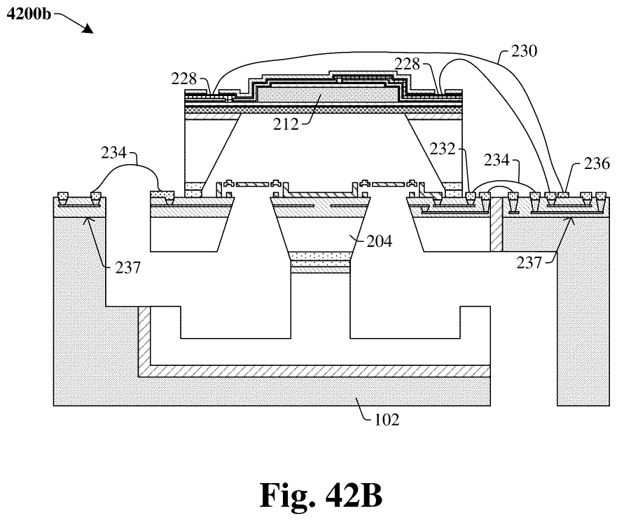

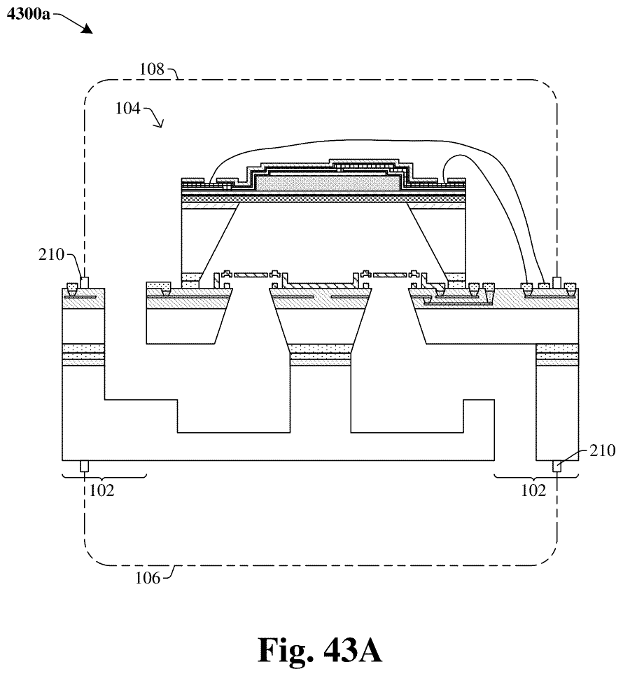

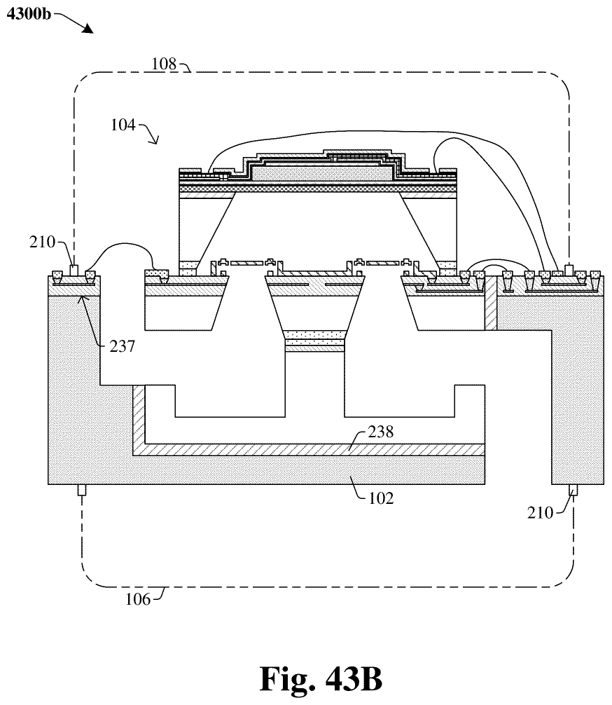

As shown in the cross-sectional view 4200a of FIG. 42A, in some embodiments, the second conductive wires 230 are bonded between the first conductive wires 228 on the piezoelectric ceramic 212 and the conductive pads 232 on the second substrate 204 in the device array fixture 102. As shown in the cross-sectional view 4200b of FIG. 42B, in other embodiments, the second conductive wires 230 are bonded between the first conductive wires 228 on the piezoelectric ceramic 212 and the fixture contacts 236 on the second interconnect structure 237 of the device array fixture 102. In further embodiments, third conductive wires 234 are bonded between the conductive pads 232 on the second substrate 204 and the fixture contacts 236 on the second interconnect structure 237. In some embodiments, the second conductive wires 230 and/or the third conductive wires 234 are bonded using a wire bonding technique, such as ball bonding, wedge bonding, or the like.

As shown in the cross-sectional views 4300a, 4300b of FIGS. 43A and 43B, in some embodiments, the first and second elastic compartments 106, 108 are affixed to the device array fixture 102. In some embodiments, the first and second elastic compartments 106, 108 are affixed to the device array fixture 102 at fixtures 210 formed before or concurrently with the affixing of the first and second elastic compartments 106, 108 to the device array fixture 102. The fixtures 210 comprise one or more of mechanical fixtures (e.g., clamps, slots, or protrusions on the device array fixture 102), chemical bonds (e.g., adhesives applied to the elastic material and the surfaces of the device array fixture 102), a combination of the foregoing, or the like. The first and second elastic compartments 106, 108 are subsequently filled with the low compressibility fluid, and other fluids (e.g., air) are removed from the first and second elastic compartments 106, 108 as well as from the plurality of micropump structures 104.

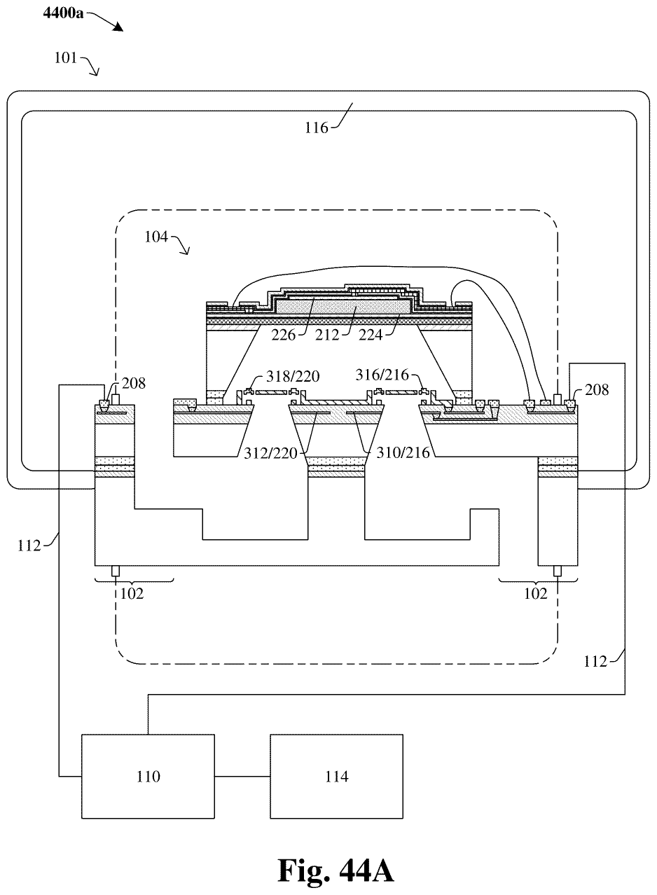

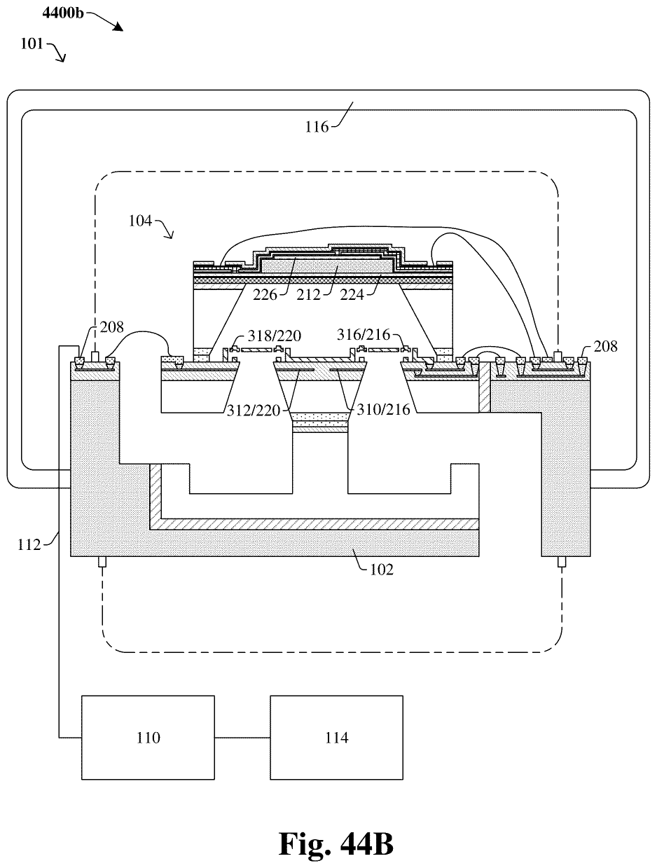

As shown in the cross-sectional views 4400a, 4400b of FIGS. 44A and 44B, the conductive wires 112 are bonded between the high voltage power source 110 and conductive contacts 208 on the device array fixture 102. The conductive contacts 208 are electrically coupled to the components (e.g., the upper and lower electrodes 226, 224 of the piezoelectric ceramic 212, the first and second body structures 316, 318 of the first and second electrostatic valves 216, 220, and the first and second electrostatic induction wires 310, 312) of the plurality of micropump structures 104. In some embodiments, control circuitry 114 is coupled to the high voltage power source 110 using one or more of integrated wires, external wires, or the like. In some embodiments, the conductive contacts 208 are all on one side of the haptic feedback device 101. Further, a belt 116 is fastened to the device array fixture 102. In some embodiments, the belt is attached to the device array fixture 102 through mechanical or chemical means. The belt 116 is configured to maintain the position of the haptic feedback device 101 in relation to a finger joint of the user to maintain operation of the device and not interfere with other haptic feedback devices coupled to the same high voltage power source 110.

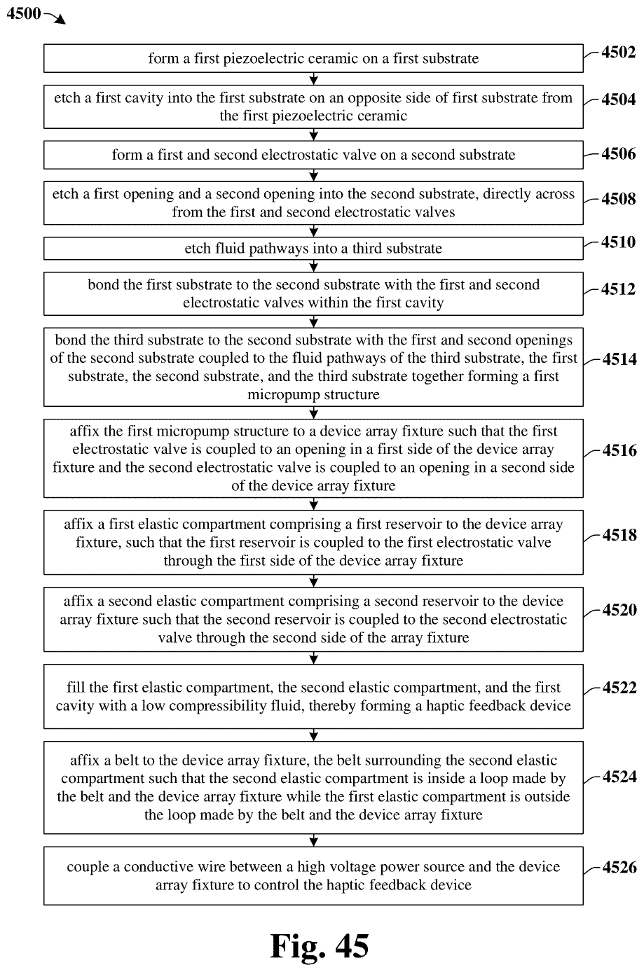

FIG. 45 illustrates a flowchart 4500 of some embodiments of a method of forming a haptic feedback device utilizing a plurality of micropump structures. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 4502, a first piezoelectric ceramic is formed on a first substrate. An example of a drawing illustrating this step can be found, for example, in FIGS. 6-7.

At 4504, a first cavity is etched into the first substrate on an opposite side of first substrate from the first piezoelectric ceramic. An example of a drawing illustrating this step can be found, for example, in FIGS. 16-17.

At 4506, a first and second electrostatic valve are formed on a second substrate. An example of a drawing illustrating this step can be found, for example, in FIG. 18-27.

At 4508, a first fluid opening and a second fluid opening are etched into the second substrate, directly across from the first and second electrostatic valves. An example of a drawing illustrating this step can be found, for example, in FIG. 31.

At 4510, fluid pathways are etched into a third substrate. An example of a drawing illustrating this step can be found, for example, in FIGS. 36-37.

At 4512, the first substrate is bonded to the second substrate with the first and second electrostatic valves within the first cavity. An example of a drawing illustrating this step can be found, for example, in FIG. 38.

At 4514, the third substrate is bonded to the second substrate with the first and second fluid openings of the second substrate coupled to the fluid pathways of the third substrate, the first substrate, the second substrate, and the third substrate together forming a first micropump structure. An example of a drawing illustrating this step can be found, for example, in FIG. 39.

At 4516, the first micropump structure is affixed to a device array fixture such that the first electrostatic valve is coupled to an opening in a first side of the device array fixture and the second electrostatic valve is coupled to an opening in a second side of the device array fixture. An example of a drawing illustrating this step can be found, for example, in FIG. 41B.

At 4518, a first elastic compartment comprising a first reservoir is affixed to the device array fixture, such that the first reservoir is coupled to the first electrostatic valve through the first side of the device array fixture. An example of a drawing illustrating this step can be found, for example, in FIGS. 43A and 43B.

At 4520, a second elastic compartment comprising a second reservoir is affixed to the device array fixture such that the second reservoir is coupled to the second electrostatic valve through the second side of the array fixture. An example of a drawing illustrating this step can be found, for example, in FIGS. 43A and 43B.

At 4522, the first elastic compartment, the second elastic compartment, and the first cavity are filled with a low compressibility fluid, thereby forming a haptic feedback device. An example of a drawing illustrating this step can be found, for example, in FIGS. 43A and 43B.

At 4524, a belt is affixed to the device array fixture, the belt surrounding the second elastic compartment such that the second elastic compartment is inside a loop made by the belt and the device array fixture while the first elastic compartment is outside the loop made by the belt and the device array fixture. An example of a drawing illustrating this step can be found, for example, in FIGS. 44A and 44B.

At 4526, a conductive wire is coupled between a high voltage power source and the device array fixture to control the haptic feedback device. An example of a drawing illustrating this step can be found, for example, in FIGS. 44A and 44B.

Some embodiments relate to an integrated device, including: a first reservoir of low compressibility fluid contained by a first elastic compartment; a second reservoir of low compressibility fluid surrounded by a second elastic compartment; a first micropump structure including: a first cavity; a first piezoelectric pump lining a first side of the first cavity; a first electrostatic valve coupling the first reservoir to the first cavity; and a second electrostatic valve coupling the second reservoir to the first cavity; and a high voltage power source coupled to the first piezoelectric pump, the first electrostatic valve, and the second electrostatic valve; and control circuitry coupled to the high voltage power source.

Other embodiments relate to an integrated device, including: a device array fixture having a first side and a second side; a first cavity within the device array fixture; a first piezoelectric ceramic covering the first cavity within the device array fixture; a first electrostatic valve within the first cavity opposite the first piezoelectric ceramic; a second electrostatic valve within the first cavity opposite the first piezoelectric ceramic; a first elastic compartment coupled to the first side of the device array fixture and the first electrostatic valve and containing a first reservoir of low compressibility fluid; a second elastic compartment coupled to the second side of the device array fixture and the second electrostatic valve and containing a second reservoir of low compressibility fluid; and a belt affixed to the device array fixture and surrounding the second elastic compartment.

Yet other embodiments relate to a method of forming an integrated device, including: forming a first micropump structure on a first plurality of substrates including: a first cavity, a piezoelectric ceramic extending over the first cavity, a first electrostatic valve coupled to the first cavity opposite the piezoelectric micropump, and a second electrostatic valve coupled to the first cavity opposite the piezoelectric micropump; affixing the first plurality of substrates to a device array fixture such that the first electrostatic valve is coupled to an opening in a first side of the device array fixture and the second electrostatic valve is coupled to an opening in a second side of the device array fixture; affixing a first elastic compartment comprising a first reservoir of low compressibility fluid to the device array fixture, such that the first reservoir is coupled to the first electrostatic valve through the first side of the device array fixture; affixing a second elastic compartment comprising a second reservoir of low compressibility fluid to the device array fixture such that the second reservoir is coupled to the second electrostatic valve through the second side of the array fixture; and affixing a belt to the device array fixture, the belt surrounding the second elastic compartment such that the second elastic compartment is inside a loop made by the belt and the device array fixture while the first elastic compartment is outside the loop made by the belt and the device array fixture.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a first reservoir of low compressibility fluid contained by a first elastic compartment;
a second reservoir of low compressibility fluid surrounded by a second elastic compartment;
a first micropump structure comprising:
a first cavity;
a first piezoelectric ceramic on a first side of the first cavity;
a first electrostatic valve coupling the first reservoir to the first cavity; and
a second electrostatic valve coupling the second reservoir to the first cavity; and
a high voltage power source coupled to the first piezoelectric ceramic, the first electrostatic valve, and the second electrostatic valve; and
control circuitry coupled to the high voltage power source.

2. The integrated device of claim 1, further comprising:
a first integrated circuit chip accommodating the first micropump structure;
a second integrated circuit chip accommodating the control circuitry and the high voltage power source; and
conductive wires extending between the first integrated circuit chip and the second integrated circuit chip, the conductive wires coupling the high voltage power source to the first piezoelectric ceramic, the first electrostatic valve, and the second electrostatic valve.

3. The integrated device of claim 2, further comprising:
a plurality of additional micropump structures coupled to the same conductive wires as the first micropump structure.

4. The integrated device of claim 1, further comprising a device array fixture isolating the first reservoir from the second reservoir and having a first side and a second side,
wherein a first fluid pathway from the first reservoir of low compressibility fluid to the first cavity extends through the first side of the device array fixture and the first electrostatic valve, and wherein a second fluid pathway from the second reservoir of low compressibility fluid to the first cavity extends through the second side of the device array fixture and the second electrostatic valve.

5. The integrated device of claim 4, further comprising a belt configured to affix the device array fixture to a finger joint, such that the first side of the device array fixture faces away from the finger joint and the second side of the device array fixture faces towards the finger joint.

6. The integrated device of claim 5, wherein the control circuitry is configured to cause the integrated device to enter a relaxed mode where the first micropump structure pumps low compressibility fluid between the first reservoir and the second reservoir such that a greater volume of low compressibility fluid is in the first reservoir than the second reservoir and the finger joint has a first range of joint movement that is unimpeded by the second elastic compartment,
wherein the control circuitry is configured to cause the integrated device to enter a grip mimicking mode where the first micropump structure pumps low compressibility fluid between the first reservoir and the second reservoir such that a greater volume of low compressibility fluid is in the second reservoir than the first reservoir and the finger joint has a second range of joint movement that is unimpeded by the second elastic compartment, and
wherein the second range of joint movement is less than the first range of joint movement.

7. The integrated device of claim 1, wherein the first micropump structure is configured to transfer low compressibility fluid between the first reservoir and the second reservoir.

8. An integrated device, comprising:
a device array fixture having a first side and a second side;
a first cavity on the first side the device array fixture;
a first piezoelectric ceramic over the first cavity;
a first electrostatic valve within the first cavity opposite the first piezoelectric ceramic;
a second electrostatic valve within the first cavity opposite the first piezoelectric ceramic;
a first elastic compartment coupled to the first side of the device array fixture and the first electrostatic valve and containing a first reservoir of low compressibility fluid;
a second elastic compartment coupled to the second side of the device array fixture and the second electrostatic valve and containing a second reservoir of low compressibility fluid; and
a belt affixed to the device array fixture and surrounding the second elastic compartment.

9. The integrated device of claim 8, further comprising a first substrate of the device array fixture, the first substrate accommodating the first cavity and the piezoelectric ceramic.

10. The integrated device of claim 9, further comprising a second substrate of the device array fixture and bonded to the first substrate opposite the piezoelectric ceramic, the second substrate accommodating:
a first fluid opening extending through the second substrate and positioned directly beneath the first cavity,
a second fluid opening spaced from the first fluid opening, extending through the second substrate, and directly beneath the first cavity,
the first electrostatic valve coupled between the first cavity and the first fluid opening, and a second electrostatic valve coupled between the first cavity and the second fluid opening.

11. The integrated device of claim 10, further comprising a third substrate of the device array fixture and bonded to the second substrate opposite the first substrate, comprising:
a first fluid pathway extending from the first fluid opening to a first side of the device array fixture; and
a second fluid pathway extending from the second fluid opening to a second side of the device array fixture.

12. The integrated device of claim 8, further comprising:
an integrated circuit chip accommodating:
a high voltage power source, and
control circuitry coupled to the high voltage power source; and
conductive wires coupling the high voltage power source to the device array fixture, electrodes on a first side of the piezoelectric ceramic and a second side of the piezoelectric ceramic, the first electrostatic valve, and the second electrostatic valve.

13. A method of forming an integrated device, comprising:
form a first micropump structure on a first plurality of substrates comprising:
a first cavity,
a piezoelectric ceramic extending over the first cavity,
a first electrostatic valve coupled to the first cavity opposite the piezoelectric ceramic, and
a second electrostatic valve coupled to the first cavity opposite the piezoelectric ceramic;
affix the first plurality of substrates to a device array fixture such that the first electrostatic valve is coupled to an opening in a first side of the device array fixture and the second electrostatic valve is coupled to an opening in a second side of the device array fixture;
affix a first elastic compartment comprising a first reservoir of low compressibility fluid to the device array fixture, such that the first reservoir is coupled to the first electrostatic valve through the first side of the device array fixture;
affix a second elastic compartment comprising a second reservoir of low compressibility fluid to the device array fixture such that the second reservoir is coupled to the second electrostatic valve through the second side of the device array fixture; and
affix a belt to the device array fixture, the belt surrounding the second elastic compartment such that the second elastic compartment is inside a loop made by the belt and the device array fixture while the first elastic compartment is outside the loop made by the belt and the device array fixture.

14. The method of claim 13, wherein forming the first micropump structure comprises:
forming a piezoelectric ceramic on a first substrate of the plurality of substrates;
etching a first cavity into the first substrate beneath the piezoelectric ceramic;
forming a first interconnect structure over a second substrate of the plurality of substrates;
forming a first electrostatic valve and a second electrostatic valve on the second substrate coupled to the first interconnect structure;
etching a first fluid opening and a second fluid opening into the second substrate beneath the first electrostatic valve and the second electrostatic valve;
bonding the second substrate to the first substrate wherein the first electrostatic valve and the second electrostatic valve extend into the first cavity;
etching a first fluid opening and a second fluid pathway into a third substrate of the plurality of substrates; and
bonding the third substrate to the second substrate opposite the first substrate such that the first fluid opening is coupled to the first electrostatic valve and the second fluid pathway is coupled to the second electrostatic valve.

15. The method of claim 14, further comprising:
forming a deflection membrane on a first side of the first substrate before forming the piezoelectric ceramic;
forming a first lower electrode over the deflection membrane before forming the piezoelectric ceramic, wherein the piezoelectric ceramic is formed on the first lower electrode;
forming a first upper electrode over the piezoelectric ceramic; and
forming conductive wires coupled to upper surfaces of the first lower electrode and the first upper electrode.

16. The method of claim 14, wherein forming the first cavity further comprises:
adhering the first substrate to a carrier wafer;
removing a portion of the first substrate opposite the piezoelectric ceramic such that the first substrate has a substantially flat surface and a thickness between 300 and 500 micrometers;
forming a first eutectic bonding layer on the substantially flat surface of the substrate; and
etching through the first substrate directly across from the piezoelectric ceramic to form the first cavity.

17. The method of claim 14, wherein forming the first interconnect structure comprises:
depositing a first wire layer comprising a semiconductor material;
patterning the first wire layer to form a first plurality of wires, comprising a first electrostatic induction wire and a second electrostatic induction wire;
forming a plurality of vias comprising a conductive metal; and
forming a second wire layer over the first wire layer electrically coupled to the first electrostatic induction wire and the second electrostatic induction wire.

18. The method of claim 14, wherein forming the first electrostatic valve and the second electrostatic valve further comprises:
forming a sacrificial insulator on a first side of the second substrate;
patterning the sacrificial insulator to form a first mold structure;
depositing a semiconductor layer comprising a doped semiconductor material over the first mold structure;
patterning the semiconductor layer, resulting in a first body structure and a second body structure surrounding the first mold structure; and
removing the first mold structure from the first body structure and the second body structure, resulting in the first electrostatic valve and the second electrostatic valve remaining on the second substrate.

19. The method of claim 13, wherein the first elastic compartment and the second elastic compartment are affixed to the device array fixture such that the device array fixture isolates the first elastic compartment from the second elastic compartment.

20. The method of claim 13, further comprising:
coupling control circuitry to a high voltage power source; and
coupling the high voltage power source to the first micropump structure.
